(19) United States
(12) Patent Application Publication
(10) Pub. No.: US 2026/0215087 A1
(43) Pub. Date: Jul. 23, 2026

(54) DISPLAY DEVICE

(71) Applicant: LG Display Co., Ltd., Seoul (KR)

(72) Inventors: MOON SUNG KIL, Paju-si (KR); EUN HYUNG LEE, Paju-si (KR); KYU IL HAN, Paju-si (KR)

(73) Assignee: LG Display Co., Ltd., Seoul (KR)

(21) Appl. No.: 19/394,699

(22) Filed: Nov. 19, 2025

(30) Foreign Application Priority Data
Jan. 23, 2025 (KR) 10-2025-0010142

(51) Int. Cl. H10K 50/18; G09G 3/3208; H10K 50/19; H10K 59/122; H10K 59/35; H10K 59/40; H10K 59/65

(52) U.S. Cl. CPC H10K 50/18; H10K 50/19; H10K 59/122; H10K 59/352; H10K 59/40; H10K 59/65; G09G 3/3208; G09G 2300/0426; G09G 2330/021

(57) ABSTRACT

A display device can include a display panel having a first display area and a second display area, and a sensor provided corresponding to the first display area. The display panel can include a substrate, a circuit layer provided on the substrate, an anode electrode provided on the circuit layer, an organic compound layer provided on the anode electrode and having a plurality of emission areas, a cathode electrode provided on the organic compound layer, and a plurality of barriers positioned in the organic compound layer.

### CROSS-REFERENCE TO RELATED APPLICATION

This application claims priority to Korean Patent Application No. 10-2025-0010142, filed in the Republic of Korea on Jan. 23, 2025, the disclosure of which is hereby expressly incorporated by reference in its entirety.

### BACKGROUND

### Technical Field

Embodiments of the present disclosure relate to a display device.

### Discussion of the Related Art

Electroluminescence display devices can be classified into inorganic light-emitting display devices and organic light-emitting displays according to a material of an emission layer. An active matrix organic light-emitting display device includes an organic light-emitting diode (OLED) that generates light by itself and has advantages in terms of a high response rate, high luminous efficiency, high luminance, and a large viewing angle. In an organic light-emitting display device, an OLED is formed at each pixel. The organic light-emitting display device has a high response rate, high luminous efficiency, high luminance, and a large viewing angle and is capable of expressing black gradation in perfect or near perfect black, thereby achieving a high contrast ratio and a high color reproduction rate.

Multi-media functions of mobile terminals are being improved. For example, a camera is built into a smart phone, and the resolution of the camera is increasing to the level of a conventional digital camera. However, the front camera of the smart phone can limit the screen design, thereby making it difficult to design the screen. In order to reduce the space occupied by the camera, a screen design including a notch or punch hole has been adopted for smart phones, but the screen size is still limited due to the notch or punch hole, thereby making it challenging to implement a full-screen display.

To implement a full-screen display, a method has been proposed in which a display area where low-resolution pixels are arranged is provided within a screen of a display panel, and electronic components such as a camera and various sensors are arranged below the display panel, at a position opposite to the display area. Here, each of the pixels can include a plurality of sub-pixels.

However, lateral leakage current flowing between adjacent light-emitting elements can occur. In addition, light generated by the lateral leakage current in the display area can affect the camera and various sensors. For example, for the camera, the light can cause color distortion in an image. In addition, for an infrared sensor, the light can cause an error in identifying a target object (such as a face).

For this reason, there is a demand for a display device having an improved structure to prevent or minimize the occurrence of light due to a lateral leakage current.

### SUMMARY OF THE DISCLOSURE

Embodiments of the present disclosure provide a display panel capable of preventing or minimizing the occurrence of light due to a lateral leakage current, and a display device including the same.

Objectives to be solved by embodiments are not limited to the objectives described above, and objectives which are not described above will be clearly understood by those skilled in the art from the following descriptions.

A display device according to an embodiment of the present disclosure includes a display panel including a first display area and a second display area; and a sensor provided corresponding to the first display area, in which the display panel includes a substrate, a circuit layer provided on the substrate, an anode electrode provided on the circuit layer, an organic compound layer that is provided on the anode electrode and includes a plurality of emission areas, a cathode electrode provided on the organic compound layer, and a plurality of barriers positioned in the organic compound layer.

A display device according to an embodiment of the present disclosure includes a substrate, a circuit layer provided on the substrate, an anode electrode provided on the circuit layer, an organic compound layer provided on the anode electrode, and a cathode electrode provided on the organic compound layer, in which the organic compound layer includes a hole injection layer, a barrier and a hole transport layer provided on the hole injection layer in contact with each other, an emission layer provided on the hole transport layer, an electron transport layer provided on the emission layer, and an electron injection layer provided on the electron transport layer, and materials of the barrier and the hole transport layer are different.

According to the embodiments of the present disclosure, it is possible to block or minimize a flow of a lateral leakage current using the barriers provided inside the organic compound layer.

According to the embodiments of the present disclosure, it is possible to block or minimize a flow of a lateral leakage current by providing barriers in some layers of a tandem structure including a plurality of emission layers.

The display device according to embodiments of the present disclosure can prevent or reduce the generation of light caused by lateral leakage current, thereby improving the performance of an optical device (or sensor). Accordingly, low-power operation of the sensor can be made possible.

Various useful advantages and effects of the embodiments are not limited to the above-described contents and will be more easily understood from descriptions of the specific embodiments.

### BRIEF DESCRIPTION OF THE DRAWINGS

The above and other objects, features, and advantages of the present disclosure will become more apparent to those of ordinary skill in the art by describing example embodiments thereof in detail with reference to the attached drawings, in which:

FIG. 1 is a diagram illustrating a display panel and a display panel driver of a display device according to embodiments of the present disclosure;

FIG. 2 is a diagram illustrating a first display area and a second display area of the display panel according to the embodiments of the present disclosure;

FIG. 3 is a cross-sectional view schematically illustrating the display panel according to the embodiments of the present disclosure;

FIG. 4 is a diagram illustrating a cross-sectional structure of a pixel area and a transmission area provided in the first display area in the display device according to the embodiments of the present disclosure;

FIG. 5 is a diagram illustrating an organic compound layer provided between an anode electrode and a cathode electrode of the first display area in the display device according to the embodiments of the present disclosure;

FIG. 6 is a cross-sectional view illustrating a cross-sectional structure of a pixel area provided in the second display area in the display panel according to the embodiments of the present disclosure;

FIG. 7 is a diagram illustrating an organic compound layer provided between an anode electrode and a cathode electrode of the second display area in the display device according to the embodiments of the present disclosure;

FIG. 8 is an enlarged view conceptually illustrating an example of an arrangement relationship of a first organic compound layer and a barrier with an A area of FIG. 4 as a reference;

FIG. 9 is an enlarged view conceptually illustrating another example of an arrangement relationship between a first organic compound layer and a barrier with the A area of FIG. 4 as a reference;

FIG. 10 is an enlarged view conceptually illustrating another example of an arrangement relationship between a first organic compound layer and a barrier with the A area of FIG. 4 as a reference;

FIG. 11 is an enlarged view conceptually illustrating another example of an arrangement relationship between a first organic compound layer and a barrier with the A area of FIG. 4 as a reference;

FIG. 12 is an enlarged view conceptually illustrating an example of an arrangement relationship between a second organic compound layer and a barrier with a B area of FIG. 6 as a reference;

FIG. 13 is an enlarged view conceptually illustrating another example of an arrangement relationship between a second organic compound layer and a barrier with the B area of FIG. 6 as a reference;

FIG. 14 is a diagram illustrating an example of a planar arrangement relationship between an emission area of a light-emitting element and a barrier in the display device according to the embodiments of the present disclosure;

FIG. 15 is a diagram illustrating another example of a planar arrangement relationship between an emission area of a light-emitting element and a barrier in the display device according to the embodiments of the present disclosure;

FIG. 16 is a diagram illustrating another example of a planar arrangement relationship between an emission area of a light-emitting element and a barrier in the display device according to the embodiments of the present disclosure; and

FIG. 17 is a diagram illustrating another example of a planar arrangement relationship between an emission area of a light-emitting element and a barrier in the display device according to the embodiments of the present disclosure.

### DETAILED DESCRIPTION OF THE EMBODIMENTS

The advantages and features of the present disclosure and methods for accomplishing the same will be more clearly understood from embodiments described below with reference to the accompanying drawings. However, the present disclosure is not limited to the following embodiments but can be implemented in various different forms. Rather, the present embodiments will make the disclosure of the present disclosure complete and allow those skilled in the art to completely comprehend the scope of the present disclosure.

Shapes, sizes, ratios, angles, numbers, and the like disclosed in the drawings for describing the embodiments of the present disclosure are examples, and the present disclosure is not limited to the illustrated items. Like reference numerals refer to like elements throughout. In addition, in describing the present disclosure, if it is determined that the detailed description of the related known technology can unnecessarily obscure the subject matter of the present disclosure, the detailed description thereof will be omitted.

The terms such as “comprising”, “including”, “having” and “consisting of” used herein are generally intended to allow other components to be added unless the terms are used with the term “only”. References to the singular shall be construed to include the plural unless expressly stated otherwise.

In interpreting a component, it is interpreted to include an error range even if there is no separate description.

In the case of a description of a positional relationship, for example, when the positional relationship of two parts is described as ‘on,’ ‘at an upper portion,’ ‘at a lower portion,’ ‘next to, and the like, one or more other parts can be located between the two parts unless ‘immediately’ or ‘directly’ is used.

In the description for the embodiments, the term such as first, second, etc. are used to describe various components, but these components are not limited by these terms. These terms are only used to distinguish one component from another. Therefore, the first component mentioned below can be a second component within the technical spirit of the present disclosure.

Throughout the specification, the same reference numerals refer to the same component.

The features of each of the various embodiments of the present disclosure can be combined or combined with each another, in whole or in part, and various technical interlocking and driving can be possible, and each of the embodiments of the present disclosure can be implemented independently of each other or in conjunction with each other.

Recently, a display device as a visual information transmission medium has been further emphasized in our information-oriented society, and display devices are being improved to meet requirements, such as low power consumption, reduction of thickness, weight reduction, high definition, high efficiency, and the like.

A display device according to one or more embodiments of the present disclosure can block or minimize a flow of a lateral leakage current using barriers provided in an organic compound layer of a display panel. Accordingly, it is possible to prevent the occurrence of light due to the lateral leakage current or to minimize an amount of light that occurs due to the lateral leakage current. As the occurrence of light due to the lateral leakage current is prevented or minimized, it is possible to prevent light from entering a sensor to increase the performance of the sensor. Therefore, the display device according to the embodiments of the present disclosure enables low-power driving of the sensor with improvement of the performance of the sensor.

Now, various features of the embodiments of the present disclosure will now be described referring to the drawings. All the components of each display apparatus/device according to all embodiments of the present disclosure are operatively coupled and configured.

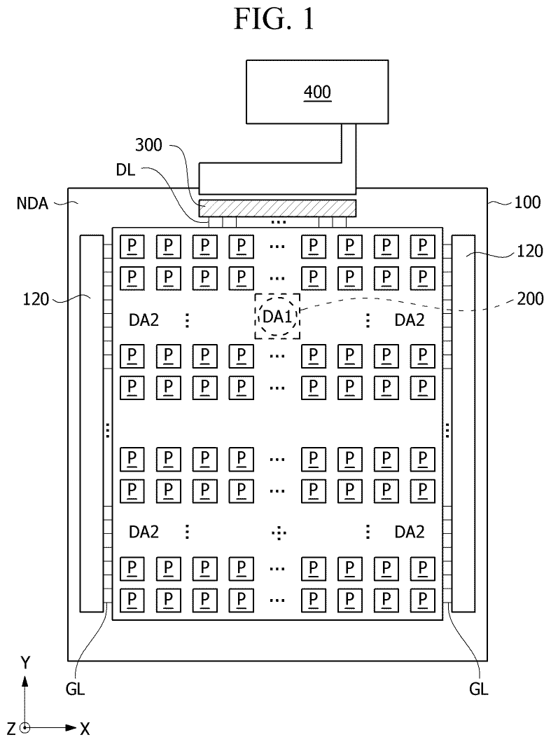

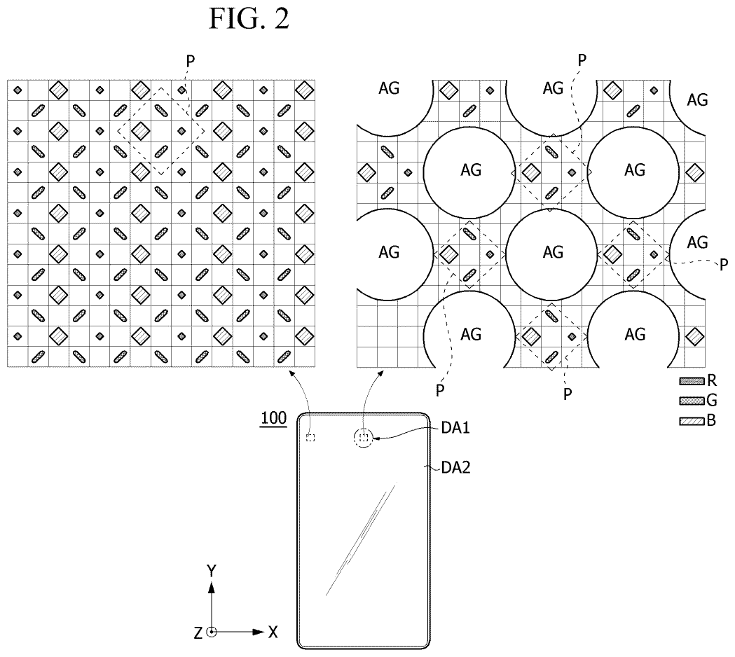

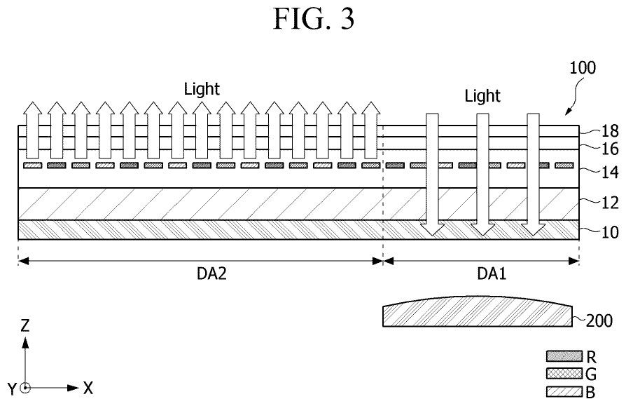

FIG. 1 is a diagram illustrating a display panel and a display panel driver of the display device according to embodiments of the present disclosure. FIG. 2 is a diagram illustrating a first display area and a second display area of the display panel according to the embodiments of the present disclosure. FIG. 3 is a cross-sectional view schematically illustrating the display panel according to the embodiments of the present disclosure.

Referring to FIGS. 1 to 3, the display device according to the embodiments of the present disclosure can include a display panel 100 and an optical device 200. The display device can further include a case that protects the display panel 100 and the optical device 200.

The display panel 100 can implement a full-screen display. The optical device 200 can include an image sensor (or a camera), a proximity sensor, a white light illumination element, an optical element for face recognition, and the like. For example, the optical device 200 can include at least one of an image sensor, a proximity sensor, an illuminance sensor, a gesture sensor, a motion sensor, a fingerprint recognition sensor, and a biosensor.

The display panel 100 can include a display area where information, a video, and/or an image are implemented, and a non-display area NDA surrounding the display area. The display area and the non-display area NDA are not necessarily described as being limited to a substrate of the display panel 100, but can be described across the overall display device.

The display area of the display panel 100 can include a first display area DA1 to which the optical device 200 is provided to correspond, and a second display area DA2 provided in the vicinity of the first display area DA1. Both the first display area DA1 and the second display area DA2 can output video. Here, the first display area DA1 can be an optical area.

The first display area DA1 and the second display area DA2 can be different in luminance. Here, luminance can represent a luminous intensity of light that is emitted in a specific direction. A grayscale (gradation) can mean a concentration level from a darkest portion to a brightest portion in an image, and can be expressed within a range of 0 to 255 in the form of eight-bit data. As an example, pixel data (R=255, G=255, B=255) in an RGB color space is grayscale values that implement luminance of peak white. The peak white can be maximum luminance that can be displayed by the display device. In the display device, when pixel data having the same grayscale value, for example, a peak white grayscale “255” is written to the pixels of the first display area DA1 and the second display area DA2, a luminance value can be different between the first display area DA1 and the second display area DA2.

The first display area DA1 and the second display area DA2 can be different in resolution. For example, the resolution of a plurality of pixels provided in the first display area DA1 can be lower than the resolution of a plurality of pixels provided in the second display area DA2. As the resolution of the plurality of pixels provided in the first display area DA1 is lowered, a sufficient amount of light can be input to the optical device 200 provided in the first display area DA1 as much. However, the display device according to the embodiments of the present disclosure is not necessarily limited thereto, and the resolution of the first display area DA1 and the resolution of the second display area DA2 can be the same as long as an the first display area DA1 has sufficient transmittance or an appropriate noise compensation algorithm can be implemented. Here, the pixels provided in the first display area DA1 can be first pixels, and the pixels provided in the second display area DA2 can be second pixels.

The first display area DA1 can be an area where the optical device 200 is provided. Because the first display area DA1 is an area overlapping various sensors and the like, the first display area DA1 can have an area relatively smaller than the second display area DA2 where most of video is output.

The first display area DA1 can be provided at various positions where light incidence is required. For example, the first display area DA1 can be provided at the center of an upper end of the display area as in FIG. 2, but is not necessarily limited thereto. The first display area DA1 can be provided on a left side or a right side of the upper end of the display area. Alternatively, the first display area DA1 can be provided at the entire upper end of the display area. Further, the first display area DA1 can be provided at the center or a lower end of the display area.

The first display area DA1 and the second display area DA2 each can include a pixel array in which pixels to which pixel data is written are provided. To secure the transmittance of the first display area DA1, the number of pixels per unit area (pixels per inch (PPI)) of the first display area DA1 can be lower than the number of pixels per unit area (pixels per inch) of the second display area DA2.

The pixel array of the second display area DA2 can include a pixel area where a plurality of pixels having a high number of pixels per unit area (pixels per inch) are provided. The pixel array of the first display area DA1 can include a pixel area where a plurality of pixels that are spaced apart from each other by transmission areas AG and have a relatively low number of pixels per unit area (pixels per inch) are provided. External light in the first display area DA1 can be transmitted through the display panel 100 through the transmission areas AG having high transmittance and received by the optical device (or a sensor) below the display panel 100.

Because both the first display area DA1 and the second display area DA2 include pixels, an input video can be reproduced on the first display area DA1 and the second display area DA2.

Each of the pixels of the first display area DA1 and the second display area DA2 can include subpixels with different colors to implement the colors of the video. The subpixels can include a red subpixel, a green subpixel, and a blue subpixel. Though not illustrated, each pixel can further include a white subpixel. Each of the subpixels can include a pixel circuit and a light-emitting element. Here, the subpixels provided in the first display area DA1 can be first subpixels, and the subpixels provided in the second display area DA2 can be second subpixels. The light-emitting element can be implemented as an organic light emitting diode (OLED).

The first display area DA1 can include pixels, and the pixels can display an input video in a display mode when pixel data of the input video is written. In this case, because the optical device 200 is provided below a bottom surface of the display panel 100 to overlap the first display area DA1, the display area of the screen is not restricted due to the optical device 200. Accordingly, the display device according to the embodiments of the present disclosure can enlarge the display area of the screen to implement a screen of a full-screen display and can increase the degree of freedom for screen design.

The first display area DA1 can include a plurality of transmission areas AG provided between a plurality of first pixels. Specifically, the first display area DA1 can include the pixels P spaced apart from each other at a predetermined distance and the transmission areas AG provided between neighboring pixels P. In this case, the subpixels of the pixels P can be provided spaced apart from each other in the pixel area of the first display area DA1. Here, an area where the pixels P are provided can represent the pixel area.
External light can be received by the optical device 200 through the light-transmitting area AG. Here, the light-transmitting area AG can include transparent media having high light transmittance to allow light to be incident with minimal light loss. For example, the light-transmitting area AG can be made of a transparent insulating material without including a metal wire or pixels. Accordingly, the light transmittance of the first display area DA1 can increase as the light-transmitting area AG becomes larger.

A shape of the light-transmitting area AG is exemplified as a rectangle, but is not limited thereto. For example, the light-transmitting area AG can be designed in various shapes such as circular, oval, and polygonal shapes.

A camera module can be provided as the optical device 200, and the camera module can capture an external image in an imaging mode and output photo or moving image data. A lens of the camera module can face the first display area DA1. In addition, the external light can be incident to a lens of the camera module through the first display area DA1, and the lens of the camera module can condense light onto an image sensor omitted from the drawings. Accordingly, the camera module can output photo or moving image data by capturing an external image in the imaging mode.

In addition, the camera module provided as the optical device 200 can be an infrared camera including an infrared sensor. Here, the infrared camera captures dot beams of infrared wavelengths focused on a person's face. In addition, the infrared camera can generate facial pattern data by converting light of an infrared wavelength passing through the display panel 100 into electrical signals and converting them into digital data. Accordingly, when the infrared-rays irradiated from an infrared illuminator are irradiated to the user's face and the infrared-rays reflected from the face are received by the infrared camera, a biometric authentication module of a host system processes the user's authentication. In this case, the infrared illuminator can enable face recognition even in a dark environment by using a flood illuminator that generates an infrared (IR) flash.

On the other hand, to secure transmittance in the first display area DA1, some pixels in the first display area DA1 can be removed. An image quality compensation algorithm for compensating for the luminance and color coordinates of the pixels provided in the first display area DA1 due to the removed pixels can be applied to the display device, but embodiments of the present disclosure are not necessarily limited thereto.

The non-display area NDA can be an area where a video is not displayed. In the non-display area NDA, various wires, circuits, and the like for driving a plurality of pixels P of the display area can be provided. For example, in the non-display area NDA, various wires and driving circuits can be mounted and a pad part to which integrated circuits, printed circuits and the like are connected can be provided, but embodiments of the present disclosure are not limited thereto.

The driving circuits can be a data driving circuit and/or a gate driving circuit, but embodiments of the present disclosure are not limited thereto. Wires through which control signals for controlling the driving circuits are supplied can be provided in the display panel 100. For example, the control signals can include various timing signals including a clock signal, an input data enable signal, and synchronization signals, but embodiments of the present disclosure are not limited thereto. In this case, the control signals can be received via the pad part.

The non-display area NDA can include a bending area. Here, the bending area can be a bendable area. In this case, a remaining area of a substrate 10 excluding the bending area can be flat. Further, the pad part can be provided in the non-display area NDA.

The display panel 100 can have a width in the X-axis direction, a length in the Y-axis direction, and a thickness in the Z-axis direction. Here, the width and length of the display panel 100 can be set to various design values depending on application fields of the display device. In addition, the X-axis direction can mean a width direction or a horizontal direction, the Y-axis direction can mean a longitudinal direction or a vertical direction, and the Z-axis direction can mean a vertical direction, a stacking direction, or a thickness direction. Here, the X-axis direction, the Y-axis direction, and the Z-axis direction can be perpendicular to each other, but can also mean different directions that are not perpendicular to each other. Each of the X-axis direction, the Y-axis direction, and the Z-axis direction can be described as one of a first direction, a second direction, or a third direction. Further, the plane extended in the X-axis direction and the Y-axis direction can mean a horizontal plane.

The display panel 100 can include a circuit layer 12 disposed on the substrate 10 and a light-emitting element layer 14 disposed on the circuit layer 12. In addition, the display panel 100 can include a encapsulation layer 16 disposed on the light-emitting element layer 14 and a touch sensor layer 18 disposed on the encapsulation layer 16.

The substrate 10 can be formed of an insulating material or a material having flexibility. For example, the substrate 10 can be made of glass, metal, or plastic, but is not limited thereto.

The circuit layer 12 can include a pixel circuit connected to wirings such as data lines, gate lines, and power lines, a gate driver connected to the gate lines, and the like. Further, the circuit layer 12 can include transistors implemented with thin film transistors (TFTs) and circuit elements such as capacitors or the like. Here, the wirings and circuit elements of the circuit layer 12 can be implemented with a plurality of insulating layers, two or more metal layers separated with the insulating layer interposed therebetween, and an active layer including a semiconductor material.

The light-emitting element layer 14 can include a light-emitting element driven by a pixel circuit. Here, the light-emitting element can be implemented with an organic light emitting diode (OLED). The OLED can include an organic compound layer formed between an anode and a cathode. The organic compound layer includes a hole injection layer (HIL), a hole transport layer (HTL), an emission layer (EML), an electron transport layer (ETL), and an electron injection layer (EIL), but is not limited thereto. When a voltage is applied to an anode and an cathode of the OLED, the holes passing through the hole transport layer (HTL) and the electrons passing through the electron transport layer (ETL) can be moved to the light emitting layer (EML) to form excitons and emit visible light from the light emitting layer (EML).

The light-emitting element layer 14 can further include a color filter array disposed on the pixels to selectively transmit red, green, and blue wavelengths.

The light-emitting element layer 14 can be covered by a protective film, and the protective film can be covered by an encapsulation layer. Here, the protective film can have a structure in which organic films and inorganic films are alternately stacked. In this case, the inorganic film can block penetration of moisture or oxygen. In addition, the organic film can planarize the surface of the inorganic film. When the organic film and the inorganic film are stacked in multiple layers, a movement path of moisture or oxygen is longer than that of a single layer, so that the penetration of moisture/oxygen affecting the light-emitting element layer 14 can be effectively blocked.

The encapsulation layer 16 covers the light-emitting element layer 14 so as to seal the circuit layer 12 and the light-emitting element layer 14. Here, the encapsulation layer 16 can have a multi-insulation film structure in which the organic film and the inorganic film are alternately stacked. In this case, the inorganic film blocks penetration of moisture or oxygen. In addition, the organic film planarizes the surface of the inorganic film. When the organic film and the inorganic film are stacked in multiple layers, the movement path of moisture or oxygen is longer than that of a single layer, so that the penetration of moisture/oxygen affecting the light-emitting element layer 14 can be effectively blocked.

The touch sensor layer 18 can include capacitive touch sensors that sense a touch input based on a change in capacitance before and after the touch input. The touch sensor layer 18 can include metal wiring patterns and insulating films forming capacitance of the touch sensors. The insulating films can insulate portions in which the metal wiring patterns are intersected and planarize the surface of the touch sensor layer.

A polarizing plate omitted in the drawing can be adhered on the touch sensor layer 18. The polarizing plate can improve visibility and contrast ratio by converting polarization of external light reflected by the metal patterns of the circuit layer 12. Further, a cover glass omitted from the drawings can be adhered on the polarizing plate.

The color filter layer can be formed on the touch sensor layer 18. The color filter layer can include red, green, and blue color filters. In addition, the color filter layer can further include a black matrix pattern. The color filter layer can absorb some wavelengths of light reflected from the circuit layer 12 to replace the role of a polarizing plate and increase color purity. A cover glass omitted in the drawings can be adhered on the color filter layer.

The color filter layer can include an organic film covering the color filter and the black matrix pattern. An extended portion of the organic film can cover the remaining inorganic film or the substrate 10 in the bezel area, for example, the edge area of the display panel 100.

The display device according to embodiments of the present disclosure can include the display panel 100 having a pixel array arranged on a screen, the display panel driver, etc.

The pixel array of the display panel 100 can include data lines DL, gate lines GL intersecting the data lines DL, and pixels connected to the data lines DL and gate lines GL and arranged in a matrix.

The pixel array can be divided into a circuit layer 12 and a light-emitting element layer 14, as shown in FIG. 3. Then, a touch sensor array can be arranged on the light-emitting element layer 14. Here, each of the pixels of the pixel array can include two to four sub-pixels, but is not necessarily limited thereto. Each of the sub-pixels can include a pixel circuit arranged in the circuit layer 12.

Each of the sub-pixels of the first display area DA1 and the second display area DA2 can include a pixel circuit. The pixel circuit can include a driving element to supply current to the light-emitting element (OLED), a plurality of switching elements to sample a threshold voltage of the driving element and switch a current path of the pixel circuit, a capacitor to maintain a gate voltage of the driving element, etc. In this case, the pixel circuit can be arranged below the light-emitting element.

The display panel driver can write pixel data of an input image into the pixels P. The pixels P can be interpreted as a pixel group including a plurality of sub-pixels.

The display panel driver can include a data driver that supplies a data voltage of pixel data to the data lines DL and a gate driver 120 that sequentially supplies gate pulses to the gate lines GL. Further, the data driver can be integrated into the drive IC 300. In addition, the display panel driver can further include a touch sensor driver omitted from the drawings.

The drive IC 300 can be bonded on the display panel 100. The drive IC 300 receives pixel data of an input image and a timing signal from the host system 400, supplies a data voltage of the pixel data to pixels, and synchronizes the data driver and the gate driver 120.

The drive IC 300 can be connected to the data lines DL through data output channels to supply data voltages of pixel data to the data lines DL. The drive IC 300 can output a gate timing signal for controlling the gate driver 120 through gate timing signal output channels.

The gate driver 120 can include a shift register formed on a circuit layer of the display panel 100 together with a pixel array. The shift register of the gate driver 120 can sequentially supply gate signals to the gate lines GL under the control of the timing controller. The gate signal can include a scan pulse and an EM pulse of an emission signal.

The host system 400 can be implemented with an application processor (AP). The host system 400 can transmit pixel data of an input image to the drive IC 300 through a mobile industry processor interface (MIPI). For example, the host system 400 can be connected to the drive IC 300 through a flexible printed circuit (FPC).

Meanwhile, the display panel 100 can be implemented with a flexible panel applicable to a flexible display.

The flexible panel can be made of a so-called “plastic OLED panel”. The plastic OLED panel can include a back plate and a pixel array on an organic thin film adhered on the back plate. A touch sensor array can be formed over the pixel array.

The back plate can be a polyethylene terephthalate (PET) substrate. The pixel array and the touch sensor array can be formed on the organic thin film. The back plate can block moisture permeation toward the organic thin film so that the pixel array is not exposed to humidity.

The organic thin film can be a polyimide (PI) substrate. A multi-layered buffer film can be formed on the organic thin film with an insulating material. Further, the circuit layer 12 and the light-emitting element layer 14 can be stacked on the organic thin film.

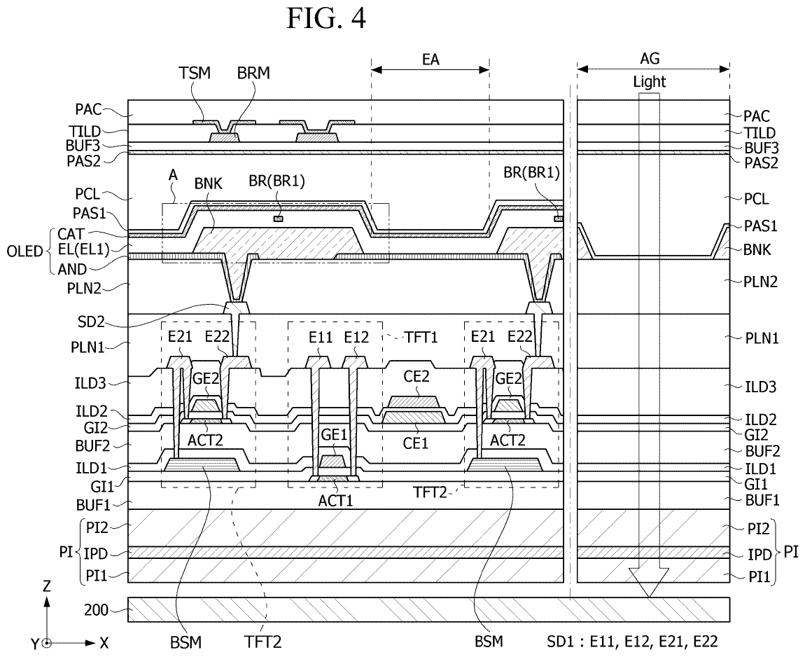

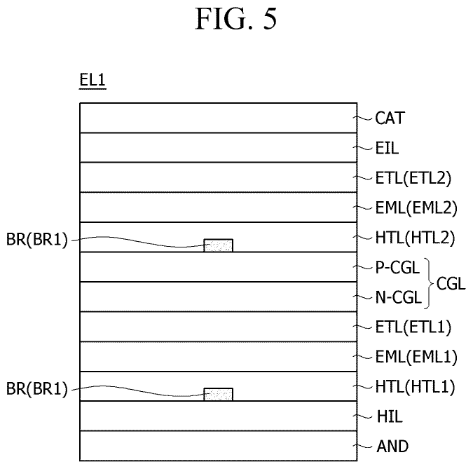

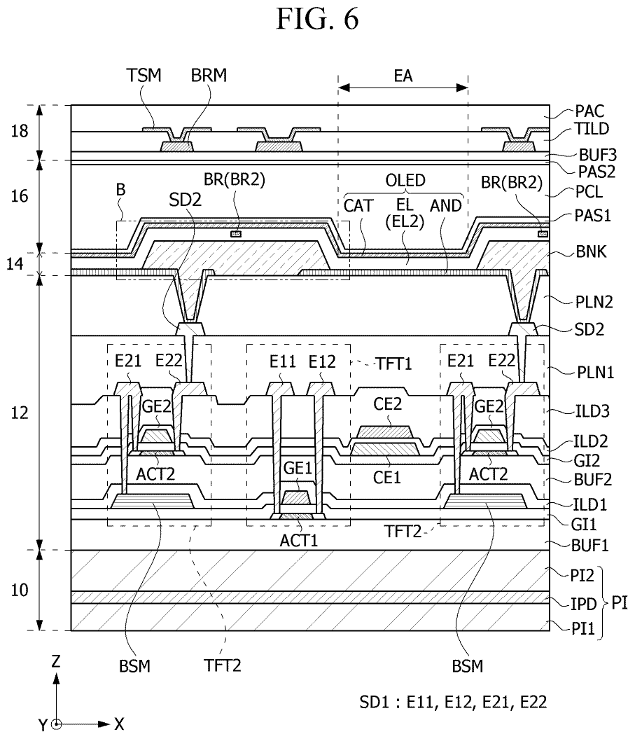

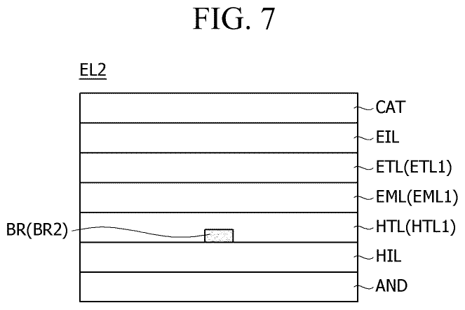

FIG. 4 is a diagram illustrating a cross-sectional structure of a pixel area and a transmission area provided in the first display area in the display device according to the embodiments of the present disclosure. FIG. 5 is a diagram illustrating an organic compound layer provided between an anode electrode and a cathode electrode of the first display area in the display device according to the embodiments of the present disclosure. For example, FIG. 5 is a diagram schematically illustrating a first organic compound layer EL1 of a first subpixel provided in a first pixel of the first display area DA1. FIG. 6 is a cross-sectional view illustrating a cross-sectional structure of a pixel area provided in the second display area in the display panel according to the embodiments of the present disclosure. FIG. 7 is a diagram illustrating an organic compound layer provided between an anode electrode and a cathode electrode of the second display area in the display device according to the embodiments of the present disclosure. For example, FIG. 7 is a diagram schematically illustrating a second organic compound layer EL2 of a second subpixel provided in a second pixel of the second display area DA2. Here, it should be noted that the cross-sectional structure of the pixel area is not limited to that of FIGS. 4 and 6. In FIGS. 4 and 6, TFT can represent a driving element of the pixel circuit. In detail, reference number TFT1 can be a first TFT that is one of LTPS TFTs provided in the display area, and reference number TFT2 can be a second TFT that is one of oxide TFTs provided in the display area.

Referring to FIGS. 2, 4, and 6, the first display area DA1 can include a pixel area and transmission areas AG. The second display area DA2 can include a pixel area.

The pixel area of each of the first display area DA1 and the second display area DA2 can be an area where a plurality of subpixels are provided, and the plurality of subpixels can generate light. For example, when power is applied to an organic compound layer EL, the organic compound layer EL can generate light. In this case, an area where light is generated in the organic compound layer EL can be an emission area EA.

In the first display area DA1 of the display panel 100, a plurality of pixel circuits and wires connected to the pixel circuits can be provided. Here, the pixel circuits of the display area can include a pixel circuit of a red subpixel for driving a red light-emitting element, a pixel circuit of a green subpixel for driving a green light-emitting element, and a pixel circuit of a blue subpixel for driving a blue light-emitting element. The pixel circuits can be separated into a plurality of circuit areas along the X-axis direction of the display panel 100 in the second display area DA2.

The substrate PI can include first and second substrates PI1 and PI2. In addition, an inorganic film IPD can be formed between the first substrate PI1 and the second substrate PI2. In this case the inorganic film IPD can block moisture permeation. Here, since the substrate PI can be formed of polyimide, it can be referred to as a PI substrate, and the first and second substrates PI1 and PI2 can be referred to as first and second PI substrates.

The first buffer layer BUF1 can be formed on the second substrate PI2. The first buffer layer BUF1 can be formed of a multi-layered insulating layer in which two or more oxide layers SiO₂ and nitride layers SiNx are stacked. A first semiconductor layer is formed on the first buffer layer BUF1. The first semiconductor layer can include a polysilicon semiconductor layer patterned in a photolithography process. The first semiconductor layer can include a polysilicon active pattern ACT1 forming a semiconductor channel in the first TFT TFT1.

A first gate insulating layer GI1 is deposited on the first buffer layer BUF1 to cover the active pattern ACT1 of the first semiconductor layer. The first gate insulating layer GI1 includes an inorganic insulating material layer. A first metal layer is formed on the first gate insulating layer GI1. The first metal layer is insulated from the first semiconductor layer by the first gate insulating layer GI1.

The first metal layer can include a single metal layer patterned in a photolithography process or metal patterns in which two or more metal layers are stacked. The first metal layer can include the gate electrode GE1 of the first TFT TFT1 and a light shield pattern BSM under the second TFT TFT2.

A first interlayer insulating layer ILD1 is formed on the first gate insulating layer GI1 to cover the patterns of the first metal layer. The first interlayer insulating layer ILD1 can include an inorganic insulating material. A second buffer layer BUF2 is formed on the first interlayer insulating layer ILD1. The second buffer layer BUF2 can include a single layer or a multi-layer inorganic insulating material.

The second semiconductor layer can include an oxide semiconductor pattern ACT2 forming a semiconductor channel in the second TFT TFT2. The second gate insulating layer GI2 can be deposited on the second buffer layer BUF2 to cover the active pattern ACT2 of the second semiconductor layer. The second gate insulating layer GI2 can include a single or multi-layered inorganic insulating material. A second metal layer can be formed on the second gate insulating layer GI2. The second metal layer can be insulated from the second semiconductor layer by the second gate insulating layer GI2.

The second metal layer can include a single metal layer patterned in a photolithography process or metal patterns in which two or more metal layers are stacked. The second metal layer can include a gate electrode GE2 of the second TFT TFT2 and a lower capacitor electrode CE1.

A second interlayer insulating layer ILD2 can be formed on the second gate insulating layer GI2 to cover the patterns of the second metal layer. The second interlayer insulating layer ILD2 can include a single layer or a multi-layer inorganic insulating material. A third metal layer can be formed on the second interlayer insulating layer ILD2. The third metal layer can be insulated from the second metal layer by the second interlayer insulating layer ILD2.

The third metal layer can include a single metal layer patterned in a photolithography process or metal patterns in which two or more metal layers are stacked. The third metal layer can include an upper capacitor electrode CE2. The capacitor Cst of the pixel circuit can be composed of the upper capacitor electrode CE2, the lower capacitor electrode CE1, and a dielectric layer therebetween, for example, the second interlayer insulating layer ILD2.

A third interlayer insulating layer ILD3 covering the patterns of the third metal layer can be formed on the second interlayer insulating layer ILD2. The third interlayer insulating layer ILD3 can include a single layer or a multi-layer inorganic insulating material. A fourth metal layer can be formed on the third interlayer insulating layer ILD3. The fourth metal layer can be insulated from the second semiconductor layer by the second gate insulating layer GI2.

A fourth metal layer SD1 can include a single metal layer patterned in a photolithography process or metal patterns in which two or more metal layers are stacked. The fourth metal layer can include first and second electrodes E11 and E12 of the first TFT TFT1 and first and second electrodes E21 and E22 of the second TFT TFT2. The first and second electrodes E11 and E12 of the first TFT TFT1 can be connected to a first active pattern ACT1 through a first contact hole passing through the insulating layers GI1, ILD1, BUF2, GI2, ILD2 and ILD3. The first and second electrodes E21 and E22 of the second TFT TFT2 can be connected to a second active pattern ACT2 through a second contact hole passing through the insulating layers GI2, ILD2 and ILD3. The first electrode E21 of the second TFT TFT2 can be connected to the light shield pattern BSM through a third contact hole passing through the insulating layers ILD1, BUF2, GI2, ILD2 and ILD3. Here, a strong electric field can be generated in the metal patterns E11 to E22 of the fourth metal layer due to voltages swinging between a gate-on voltage and a gate-off voltage with a large voltage difference.

A first planarization layer PLN1 can cover the metal patterns E11 to E22 of the fourth metal layer. The first planarization layer PLN1 can thickly cover the second display area DA2 of the circuit layer 12 with an organic insulating material. When the first planarization layer PLN1 is applied on the circuit layer 12, the organic insulating material can flow to the edge of the display panel 100 and cover the side surface of the circuit layer 12.

A fifth metal layer can be formed on the first planarization layer PLN1. The fifth metal layer can be insulated from the fourth metal layer by the first planarization layer PLN1. The fifth metal layer can include a single metal layer patterned in a photolithography process or metal patterns in which two or more metal layers are stacked. The fifth metal layer can include a metal pattern SD2 connecting the light-emitting element to the second TFT TFT2. The metal pattern SD2 can be connected to the second electrode E22 of the second TFT TFT2 through a fourth contact hole penetrating the first planarization layer PLN1.

A second planarization layer PLN2 can be formed on the first planarization layer PLN1 to cover the metal patterns of the fifth metal layer. The second planarization layer PLN2 can thickly cover the second display area DA2 of the circuit layer 12 with an organic insulating material. A sixth metal layer can be formed on the second planarization layer PLN2. The second planarization layer PLN2 can planarize the surface on which the sixth metal layer is formed.

The sixth metal layer can include a single metal layer patterned in a photolithography process or metal patterns in which two or more metal layers are stacked. The pattern of the sixth metal layer can include an anode electrode AND of the light emitting element. The anode electrode AND can be in contact with the metal pattern SD2 connected to the second TFT TFT2 of the pixel circuits through the fifth contact hole penetrating the second planarization layer PLN2.

In the light emitting element layer 14, a bank BNK can be formed on the second planarization layer PLN2 to cover the edge of the anode electrode AND. In this case, the bank BNK can be formed in a pattern that divides an emission area (or an opening area) from which light is emitted from each pixel to the outside. Accordingly, the bank BNK can be referred to as a pixel-defining film. The bank BNK can be patterned in a photolithography process by including an organic insulating material having photosensitivity. Further, a spacer SPC having a predetermined height can be formed on the bank BNK, but is not limited thereto.

A seventh metal layer used as a cathode electrode CAT of the light-emitting element can be formed on the bank BNK and the organic compound layer EL. The seventh metal layer can be connected between sub-pixels in the display area DA. Here, the organic compound layer EL can be referred to as a light emitting layer or an electroluminescent layer.

The encapsulation layer 16 can include multiple insulating layers covering the cathode electrode CAT of the light emitting device. The multiple insulating layers can include a first inorganic insulating layer PAS1 covering the cathode electrode CAT, a thick organic insulating layer PCL covering the first inorganic insulating layer PAS1, and a second inorganic insulating layer PAS2 covering the organic insulating layer PCL.

The touch sensor layer 18 can include a third buffer layer BUF3 covering the second inorganic insulating layer PAS2, a bridge metal BRM arranged on the third buffer layer BUF3, a touch interlayer insulating layer TILD of an inorganic material covering the bridge metal BRM, a touch sensor metal TSM arranged above the bridge metal BRM, and an organic insulating layer PAC covering the touch interlayer insulating layer TILD and the touch sensor metal TSM. Here, the third buffer layer BUF3 can be a touch buffer layer.

An eighth metal layer used as the bridge metal BRM can be arranged on the third buffer layer BUF3 and can overlap the bank BNK. The eighth metal layer can include a single-metal layer or a stacked-metal layer, comprising two or more metal layers, patterned through the photolithography process.

The ninth metal layer can include a single-metal layer or a stacked-metal layer, comprising two or more metal layers, patterned through the photolithography process. A pattern of the ninth metal layer can include the touch sensor metal TSM. The touch sensor metal TSM can be in contact with the bridge metal BRM through a sixth contact hole through the touch interlayer insulating layer TILD.

A plurality of transmission areas AG can be provided between a plurality of first pixels provided in the first display area DA1. Specifically, the first display area DA1 can include the first pixels spaced apart from each other at a predetermined distance, and the transmission areas AG provided between the first pixels. External light can be received by the optical device 200 such as a camera module via the transmission areas AG.

The transmission areas AG can include transparent media having high transmittance with no metal such that light can be incident with minimum light loss. The transmission areas AG can be made of transparent insulating materials without including metal wires or pixels. Accordingly, as the transmission areas AG are greater, the transmittance in the first display area DA1 can be higher.

Referring to FIGS. 4 to 7, the light-emitting element OLED that composes the subpixel in the display device according to the embodiments of the present disclosure can include the organic compound layer EL provided between the anode electrode AND and the cathode electrode CAT. The organic compound layer EL can include the hole injection layer HIL, the hole transport layer HTL provided on the hole injection layer HIL, the emission layer EML provided on the hole transport layer HTL, the electron transport layer ETL provided on the emission layer EML, and the electron injection layer EIL provided on the electron transport layer ETL. In this case, the anode electrode AND can be independently provided corresponding to each light-emitting element OLED, but embodiments of the present disclosure are not necessarily limited thereto.

The luminance of the first display area DA1 can be different from the luminance of the second display area DA2 due to the transmission areas AG and the like in the display device according to the embodiments of the present disclosure. Accordingly, the display device according to the embodiments of the present disclosure can secure luminance in the first display area DA1 using a tandem structure including at least two emission layers EML. For example, the first organic compound layer EL1 of the first display area DA1 can be formed in a tandem structure including at least two emission layers EML. In this case, the second organic compound layer EL2 of the second display area DA2 can include one emission layer EML.

Referring to FIG. 5, the subpixels provided in the first pixels of the first display area DA1 can include the first organic compound layer EL1 provided between the anode electrode AND and the cathode electrode CAT.

The first organic compound layer EL1 can include one hole injection layer HIL, one charge generation layer CGL, and one electron injection layer EIL, and can include two hole transport layers HTL, two electron transport layers ETL, and two emission layers EML, but embodiments of the present disclosure are not necessarily limited thereto. For example, the first organic compound layer EL1 can include the hole injection layer HIL, a first hole transport layer HTL1 provided on the hole injection layer HIL, a first emission layer EML1 provided on the first hole transport layer HTL1, a first electron transport layer ETL1 provided on the first emission layer EML1, a charge generation layer CGL provided on the first electron transport layer ETL1, a second hole transport layer HTL2 provided on the charge generation layer CGL, a second emission layer EML2 provided on the second hole transport layer HTL2, a second electron transport layer ETL2 provided on the second emission layer EML2, and the electron injection layer EIL provided on the second electron transport layer ETL2.

The hole injection layer HIL can be provided on the anode electrode AND and can serve to make hole injection smoothly. The hole injection layer HIL can be made of one or more selected from a group consisting of 1,4,5,8,9,11-hexaazatriphenylene-hexanitrile (HATCN), copper phthalocyanine (CuPc), poly(3,4)-ethylenedioxythiophene (PEDOT), polyaniline (PANI), and N, N-dinaphthyl-N, N'-diphenylbenzidine (NPD), but embodiments of the present disclosure are not limited thereto.

The first hole transport layer HTL1 can be provided on the hole injection layer HIL and can serve to make hole transport smoothly. The first hole transport layer HTL1 can be made of one or more selected from a group consisting of N,N-dinaphthyl-N,N′-diphenylbenzidine (NPD), N,N′-bis-(3-methylphenyl)-N,N′-bis-(phenyl)-benzidine (TPD), s-TAD, and 4,4′,4″-Tris(N-3-methylphenyl-N-phenyl-amino)-triphenylamine (MTDATA), but embodiments of the present disclosure are not limited thereto.

The first emission layer EML1 can be provided on the first hole transport layer HTL1 and can generate light. The first emission layer EML1 can include a light emitting material, and can generate light having a different wavelength according to the light emitting material. For example, the first emission layer EML1 can include at least one of a light emitting material that emits red light, a light emitting material that emits green light, and a light emitting material that emits blue light.

The first electron transport layer ETL1 can be provided on the first emission layer EML1 and can serve to electron transport smoothly. The first electron transport layer ETL1 can be made of one or more selected from a group consisting of tris(8-hydroxy-quinolinato)aluminum (Alq3), 2-(4-biphenyl)-5-(4-tert-butylphenyl)-1,3,4-oxadiazole (PBD), 3-(4-biphenyl)4-phenyl-5-tert-butylphenyl-1,2,4-triazole (TAZ), spiro-PBD, bis(2-methyl-8-quiolinolate)-4-(phenylphenolato)aluminum (BAlq), 8-hydroxyquinolinolato-lithium (Liq), 5,5′-bis(dimethylboryl)-2,2′:5′,2″-terthiophene (BMB-3T), perfluoro-2-naphthyl-substituted (PF-6P), 2,2′,2″-(1,3,5-benzinetriyl)-tris(1-phenyl-1-H-benzimidazole) (TPBi), and cyclooctatetracene (COT), but embodiments of the present disclosure are not limited thereto.

The charge generation layer CGL can be provided on the first electron transport layer ETL1 and can supply electrons to the first electron transport layer ETL1. Further, the charge generation layer CGL can supply holes to the second hole transport layer HTL2 provided on the charge generation layer CGL.

The charge generation layer CGL can include an N-type charge generation layer N-CGL provided on the first electron transport layer ETL1 and a P-type charge generation layer P-CGL provided on the N-type charge generation layer N-CGL. The N-type charge generation layer N-CGL can supply electrons to the first electron transport layer ETL1. The P-type charge generation layer P-CGL can supply holes to the second hole transport layer HTL2.

The N-type charge generation layer N-CGL can be an organic layer doped with alkali metal such as Li, Na, K, or Cs and/or alkaline-earth metal such as Mg, Sr, Ba, or Ra.

The P-type charge generation layer P-CGL can be made by doping a hole injection material, which is one selected from MTDATA, CuPc, TCTA, NPB (NPD), HATCN, TDAPB, PEDOT/PSS, F4TCNQ, N-(biphenyl-4-yl)-9,9-dimethyl-N-(4-(9-phynyl-9H-carbazol-3-yl)phenyl)-9H-fluoren-2-amine, and/or the like, with an organic compound.

The second hole transport layer HTL2 can be provided on the P-type charge generation layer P-CGL and can serve to make hole transport smoothly. In this case, the second hole transport layer HTL2 can include the same material as the first hole transport layer HTL1, but embodiments of the present disclosure are not necessarily limited thereto.

The second emission layer EML2 can be provided on the second hole transport layer HTL2 and can generate light. The second emission layer EML2 can include a light emitting material, and can generate light having a different wavelength according to the light emitting material. For example, the second emission layer EML2 can include at least one of a light emitting material that emits red light, a light emitting material that emits green light, and a light emitting material that emits blue light.

The second electron transport layer ETL2 can be provided on the second emission layer EML2 and can serve to make electron transport smoothly. In this case, the second electron transport layer ETL2 can include the same material as the first electron transport layer ETL1, but embodiments of the present disclosure are not necessarily limited thereto.

The electron injection layer EIL can serve to make electron injection on the second electron transport layer ETL2 smoothly.

The electron injection layer EIL can include a compound such as tris(8-hydroxyquinolino) aluminum (Alq3), 2-(4-biphenylyl)-5-(4-tert-butylpheny)-1,3,4oxadiazole (PBD), TAZ, spiro-PBD, BAlq, or SAlq, but embodiments of the present disclosure are not limited thereto. The electron injection layer EIL can be made of a metal compound, and the metal compound can include Liq, LiF, NaF, KF, RbF, CsF, FrF, BeF2, MgF2, CaF2, SrF2, BaF2, RaF2, or the like, but embodiments of the present disclosure are not limited thereto.

The subpixels provided in the second pixels of the second display area DA2 can include the second organic compound layer EL2 provided between the anode electrode AND and the cathode electrode CAT. The second organic compound layer EL2 can include the hole injection layer HIL, the first hole transport layer HTL1, the first emission layer EML1, the first electron transport layer ETL1, and the electron injection layer EIL provided on the first electron transport layer ETL1. The hole injection layer HIL, the first hole transport layer HTL1, the first emission layer EML1, and the first electron transport layer ETL1 of the second organic compound layer EL2 can be substantially the same arrangement structure as the hole injection layer HIL, the first hole transport layer HTL1, the first emission layer EML1, and the first electron transport layer ETL1 of the first organic compound layer EL1. Thus, these layers are given the same reference numbers, and redundant description thereto will be omitted or simplified.

The electron injection layer EIL of the second organic compound layer EL2 is different in arrangement from the electron injection layer EIL of the first organic compound layer EL1 in that the electron injection layer EIL is provided on the first electron transport layer ETL1, and can serve similarly to the electron injection layer EIL of the first organic compound layer EL1. For example, the electron injection layer EIL of the second organic compound layer EL2 can serve to make electron injection into the first electron transport layer ETL1 smoothly.

Because the organic compound layer EL of the display panel 100 can include a plurality of emission areas EA, a lateral leakage current can flow through the organic compound layer EL provided two light-emitting elements OLED provided neighboring to each other. Light can occur in the light-emitting element OLED due to the lateral leakage current.

As the full-screen display is implemented in the display device, light that occurs due to the lateral leakage current can affect the camera and various sensors.

Because the first display area DA1 of the display panel 100 can include the light-emitting element OLED formed in a tandem structure, the lateral leakage current can be more likely to occur in the first display area DA1 than in the second display area DA2. For example, a path through which the lateral leakage current can flow can be more likely to be formed in the light-emitting element formed in the tandem structure than in a light-emitting element in which one emission layer is formed. Accordingly, a probability that light occurs in the first display area DA1 due to the lateral leakage current can be increased, and as a result, a probability that light due to the lateral leakage current affects the optical device 200 can also be increased.

Therefore, in the display device according to the embodiments of the present disclosure, the flow of the lateral leakage current can be blocked or minimized by providing a separate structure on a path through which the lateral leakage current can flow.

The lateral leakage current can move along an interface between the hole injection layer HIL and the hole transport layer HTL or an interface between the P-type charge generation layer P-CGL and the hole transport layer HTL. For this reason, in the display panel 100 according to the embodiments of the present disclosure, the flow of the lateral leakage current can be blocked or minimized by depositing a barrier BR as a separate structure for reducing hole mobility inside the organic compound layer EL. For example, the flow of the lateral leakage current can be blocked or minimized by providing the barrier BR on the hole injection layer HIL along with the hole transport layer HTL or providing the barrier BR on the P-type charge generation layer P-CGL along with the hole transport layer HTL. Accordingly, the barrier BR can be provided spaced apart from the bank BNK. Here, the interface can be called a contact area. The barrier BR can be called a blocking layer, and the blocking layer can be a hole blocking layer or a lateral leakage current blocking layer. A path through which the lateral leakage current moves along the interface between the hole injection layer HIL and the hole transport layer HTL can be a first path. A path through which the lateral leakage current moves along the interface between the P-type charge generation layer P-CGL and the hole transport layer HTL can be a second path.

The display panel 100 can include a plurality of barriers BR positioned in the organic compound layer EL, and the plurality of barriers BR can include first barriers BR1 provided in the first display area DA1 and second barriers BR2 provided in the second display area DA2.

The barrier BR can be formed of a material different from the material of the hole transport layer HTL. For example, the barrier BR can include the same material as the material of the electron injection layer EIL. For example, the barrier BR can include lithium fluoride (LiF) and 8-hydroxyquinolinolato-lithium (Liq) that is used as the electron injection layer EIL.

Because the material of the barrier BR is different from the material of the hole transport layer HTL, a sheet resistance of the barrier BR can be different from a sheet resistance of the hole transport layer HTL. In this case, the sheet resistance of the barrier BR can be greater than the sheet resistance of the hole transport layer HTL, and the sheet resistance of the barrier BR can be adjusted according to the area of the barrier BR. Accordingly, the flow of the lateral leakage current that moves along the interface between the hole injection layer HIL and the hole transport layer HTL and/or the interface between the P-type charge generation layer P-CGL and the hole transport layer HTL can be blocked or minimized. Here, the sheet resistance is a value representing a resistance component of a surface of a material, and can represent resistance per unit area.

Further, because the bank BNK can divide the emission area EA where light is emitted to the outside, the barrier BR can be provided on the bank BNK in consideration of interference with the emission area EA. Accordingly, the barrier BR can be provided to overlap the bank BNK. In this case, because the barrier BR reduces hole mobility with sheet resistance, the barrier BR can be provided spaced apart from the emission area EA, but embodiments of the present disclosure are not necessarily limited thereto. Here, the bank BNK can be provided on the second planarization layer PLN2 of the circuit layer 12.

Hereinafter, the arrangement and structure of the barrier BR that can block the lateral leakage current or can minimize the occurrence of light due to the lateral leakage current even when the lateral leakage current flows will be examined.

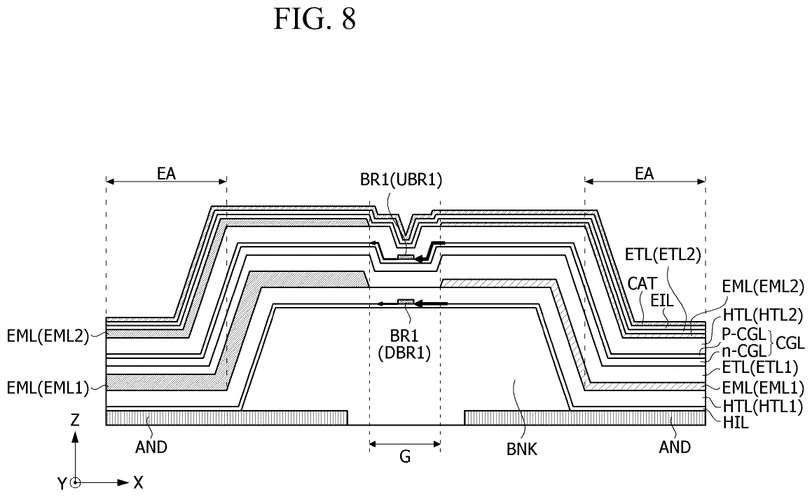

FIG. 8 is an enlarged view conceptually illustrating an example of an arrangement relationship between a first organic compound layer and a barrier with an A area of FIG. 4 as a reference. For example, FIG. 8 is an enlarged view conceptually illustrating a first embodiment of the present disclosure for an arrangement relationship between a first organic compound layer and a barrier. An arrow in FIG. 8 can represent a flow of a lateral leakage current. Here, a barrier BR illustrated in FIG. 8 can represent a first barrier according to the first embodiment.

Referring to FIG. 8, a first barrier BR1 can be provided inside the first organic compound layer EL1. In this case, the first barrier BR1 can be provided to overlap the bank BNK.

The first barrier BR1 can include a lower barrier DBR1 and an upper barrier UBR1. For example, the lower barrier DBR1 can be provided on the hole injection layer HIL along with and in contact with the first hole transport layer HTL1. The upper barrier UBR1 can be provided on the P-type charge generation layer P-CGL to be in contact with the second hole transport layer HTL2. Here, the lower barrier DBR1 can be provided on the first path of the lateral leakage current. Further, the upper barrier UBR1 can be provided on the second path of the lateral leakage current.

The first barrier BR1 illustrated in FIG. 8 represents the lower barrier DBR1 and the upper barrier UBR1 provided on the hole injection layer HIL and the P-type charge generation layer P-CGL, but embodiments of the present disclosure are not limited thereto. For example, the first barrier BR1 can be provided only on the hole injection layer HIL. Further, the first barrier BR1 can be provided only on the P-type charge generation layer P-CGL. Here, the lower barrier DBR1 can be a first lower barrier, and the upper barrier UBR1 can be a first upper barrier. Further, the first hole transport layer HTL1 can be a lower hole transport layer, and the second hole transport layer HTL2 can be an upper hole transport layer.

As the material of the hole transport layer HTL and the material of the barrier BR are different, the sheet resistance of the hole transport layer HTL and the sheet resistance of the barrier BR can be different. For this reason, the lateral leakage current can be reduced while passing through the barrier BR.

Referring to arrows illustrated in FIG. 8, the lateral leakage current can be reduced primarily in a contact area of the first lower barrier DBR1 and the hole injection layer HIL by the sheet resistance of the lower barrier DBR1. The lateral leakage current reduced primarily can be reduced secondarily in a contact area of the hole injection layer HIL and the first hole transport layer HTL1 by the sheet resistance of the first hole transport layer HTL1.

Further, the lateral leakage current can be reduced primarily in a contact area of the upper barrier UBR1 and the P-type charge generation layer P-CGL by the sheet resistance of the upper barrier UBR1. The lateral leakage current reduced primarily can be reduced secondarily in a contact area of the P-type charge generation layer P-CGL and the second hole transport layer HTL2 by the sheet resistance of the second hole transport layer HTL2.

The lower barrier DBR1 and the upper barrier UBR1 can be provided to overlap each other, and can be formed to have the same shape. Accordingly, because the same mask can be used in a manufacturing step of forming each of the lower barrier DBR1 and the upper barrier UBR1, it is possible to improve the productivity of the display panel 100.

As illustrated in FIG. 8, a part of the first hole transport layer HTL1 can be provided on the lower barrier DBR1. A part of the second hole transport layer HTL2 can be provided on the upper barrier UBR1. For example, the first hole transport layer HTL1 can be provided to cover the lower barrier DBR1, and the second hole transport layer HTL2 can be provided to cover the upper barrier UBR1.

In the first organic compound layer EL1, the emission layers EML1 and EML2 that form one emission area EA and the emission layers EML1 and EML2 that are provided neighboring thereto and form another emission area EA can be provided spaced apart from each other to have a predetermined gap G. In this case, the first emission layer EML1 and the second emission layer EML2 can be provided to overlap each other. For example, one end portion of the first emission layer EML1 and one end portion of the second emission layer EML2 can be provided to overlap each other. Accordingly, because the same mask can be used in a manufacturing step of forming each of the first emission layer EML1 and the second emission layer EML2, it is possible to improve the productivity of the display panel 100. Here, while the first emission layer EML1 and the second emission layer EML2 are provided to overlap each other as an example, but embodiments of the present disclosure are not necessarily limited thereto. For example, the first emission layer EML1 and the second emission layer EML2 can be different in width.

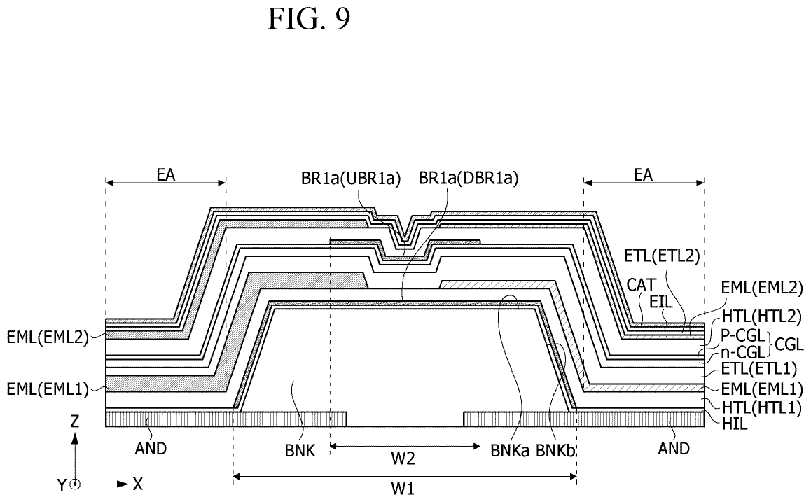

FIG. 9 is an enlarged view conceptually illustrating an example of an arrangement relationship between a first organic compound layer and a barrier with the A area of FIG. 4 as a reference. For example, FIG. 9 is an enlarged view conceptually illustrating a second embodiment of the present disclosure for an arrangement relationship between a first organic compound layer and a barrier. Here, a barrier illustrated in FIG. 9 can represent a first barrier according to the second embodiment.

Referring to FIGS. 8 and 9, a first barrier BR1a according to the second embodiment is different from the first barrier BR1 according to the first embodiment in that a width is increased. Accordingly, with the first barrier BR1a having the increased width, the lateral leakage current can be further reduced while passing through the first barrier BR1a.

The first barrier BR1a according to the second embodiment can be provided in the display panel 100 instead of the first barrier BR1 according to the first embodiment. In describing the first barrier BR1a according to the second embodiment, substantially the same components as those of the first barrier BR1 according to the first embodiment in terms of the structure are given the same reference numbers, and redundant description thereto will be omitted or simplified.

Referring to FIG. 9, the first barrier BR1a of the first organic compound layer EL1 can include a lower barrier DBR1a provided on the hole injection layer HIL along with and in contact with the first hole transport layer HTL1, and an upper barrier UBR1a provided on the P-type charge generation layer P-CGL along with and in contact with the second hole transport layer HTL2. Here, the lower barrier DBR1a can be provided on the first path of the lateral leakage current. Further, the upper barrier UBR1a can be provided on the second path of the lateral leakage current.

The lower barrier DBR1a can be formed to have a first width W1, and the upper barrier UBR1a can be formed to have a second width W2 smaller than the first width W1. In this case, the upper barrier UBR1a can overlap the lower barrier DBR1a.

A partial area of the lower barrier DBR1a can overlap an upper surface BNKa of the bank BNK. Another partial area of the lower barrier DBR1a can overlap a part or the whole of a side surface BNKb of the bank BNK. Accordingly, because a contact area of the lower barrier DBR1a and the hole injection layer HIL is increased, the lateral leakage current can be blocked or further reduced by a sheet resistance of the lower barrier DBR1a. In this case, a part of the lower barrier DBR1a can be provided to overlap a part of the first emission layer EML1 and the second emission layer EML2; however, the first width W1 of the lower barrier DBR1a can be restricted in consideration of interference with the emission area EA. Here, a partial area of the lower barrier DBR1a overlapping the upper surface BNKa of the bank BNK can be a first lower barrier area, and another partial area of the lower barrier DBR1a overlapping the side surface BNKb of the bank BNK can be a second lower barrier area. In this case, because the bank BNK can have a trapezoidal shape having predetermined height and width, the second lower barrier area can overlap the side surface BNKb of the bank BNK in the X-axis direction or the Y-axis direction. The second lower barrier area can overlap the side surface BNKb of the bank BNK in the Z-axis direction.

When the lower barrier DBR1a is provided to overlap the entire side surface BNKb of the bank BNK, one end portion of the lower barrier DBR1a can be provided adjacent to the emission area EA. Accordingly, when the light-emitting element OLED emits light, a current that is applied to the light-emitting element OLED via the anode electrode AND can be guided to the first emission layer EML1 side. For example, because the lower barrier DBR1a reduces movement of a current with sheet resistance, the current that is applied to the light-emitting element OLED via the anode electrode AND can be guided to the first emission layer EML1 side.

The upper barrier UBR1a can be formed at the second width W2 to overlap the upper surface BNKa of the bank BNK. In this case, a part of the upper barrier UBR1a can be provided to overlap a part of the first emission layer EML1 and the second emission layer EML2. Accordingly, because a contact area of the upper barrier UBR1a and the P-type charge generation layer P-CGL is increased, the lateral leakage current can be blocked or further reduced by a sheet resistance of the upper barrier UBR1a.

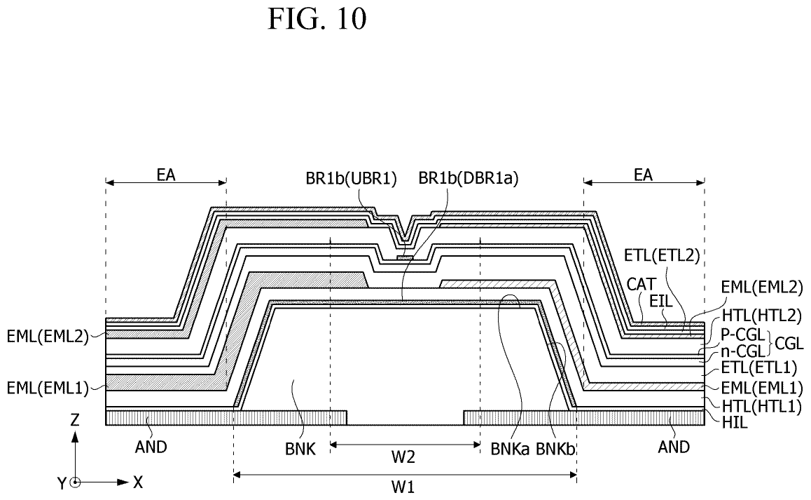

FIG. 10 is an enlarged view conceptually illustrating an example of an arrangement relationship between a first organic compound layer and a barrier with the A area of FIG. 4 as a reference. For example, FIG. 10 is an enlarged view conceptually illustrating a third embodiment of the present disclosure for an arrangement relationship between a first organic compound layer and a barrier. Here, a barrier illustrated in FIG. 10 can represent a first barrier according to the third embodiment.

Referring to FIGS. 8 to 10, a first barrier BR1b according to the third embodiment can use the lower barrier DBR1a of the first barrier BR1a according to the second embodiment instead of the lower barrier DBR1 of the first barrier BR1 according to the first embodiment.

The first barrier BR1b according to the third embodiment can be provided in the display panel 100 instead of the first barrier BR1 according to the first embodiment. In describing the first barrier BR1b according to the third embodiment, substantially the same components as those of the first barriers BR1 and BR1a according to the first and second embodiments in terms of the structure are given the same reference numbers, and redundant description thereto will be omitted or simplified.

Referring to FIG. 10, the first barrier BR1b of the first organic compound layer EL1 can include the lower barrier DBR1a provided on the hole injection layer HIL along with and in contact with the first hole transport layer HTL1, and the upper barrier UBR1 provided on the P-type charge generation layer P-CGL along with and in contact with the second hole transport layer HTL2. Here, the lower barrier DBR1a can be provided on the first path of the lateral leakage current. Further, the upper barrier UBR1 can be provided on the second path of the lateral leakage current.

The upper barrier UBR1 can overlap the lower barrier DBR1a.

A partial area of the lower barrier DBR1a can overlap the upper surface BNKa of the bank BNK. Further, another partial area of the lower barrier DBR1a can overlap a part or the whole of the side surface BNKb of the bank BNK.

The upper barrier UBR1 can overlap the upper surface BNKa of the bank BNK. In this case, the upper barrier UBR1 can be provided not to overlap the first emission layer EML1 and the second emission layer EML2.

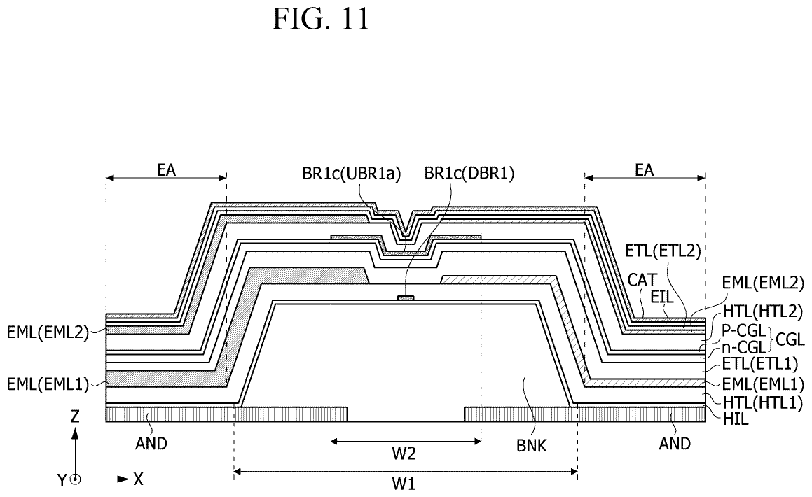

FIG. 11 is an enlarged view conceptually illustrating an example of an arrangement relationship between a first organic compound layer and a barrier with the A area of FIG. 4 as a reference. For example, FIG. 11 is an enlarged view conceptually illustrating a fourth embodiment of the present disclosure for an arrangement relationship between a first organic compound layer and a barrier. Here, a barrier illustrated in FIG. 11 can represent a first barrier according to the fourth embodiment.

Referring to FIGS. 8, 9, and 11, a first barrier BR1c according to the fourth embodiment can use the upper barrier UBR1a of the first barrier BR1a according to the second embodiment instead of the upper barrier UBR1 of the first barrier BR1 according to the first embodiment.

The first barrier BR1c according to the fourth embodiment can be provided in the display panel 100 instead of the first barrier BR1 according to the first embodiment. In describing the first barrier BR1c according to the fourth embodiment, substantially the same components as those of the first barriers BR1 and BR1a according to the first and second embodiments in terms of the structure are given the same reference numbers, and redundant description thereto will be omitted or simplified.

Referring to FIG. 11, the first barrier BR1c of the first organic compound layer EL1 can include the lower barrier DBR1 provided on the hole injection layer HIL along with and in contact with the first hole transport layer HTL1, and the upper barrier UBR1a provided on the P-type charge generation layer P-CGL along with and in contact with the second hole transport layer HTL2. Here, the lower barrier DBR1 can be provided on the first path of the lateral leakage current. Further, the upper barrier UBR1a can be provided on the second path of the lateral leakage current.

The lower barrier DBR1 can overlap the upper barrier UBR1a.

The lower barrier DBR1 can overlap the upper surface BNKa of the bank BNK. In this case, the lower barrier DBR1 can be provided not to overlap the side surface BNKb of the bank BNK.

The upper barrier UBR1a can be formed at the second width W2 to overlap the upper surface BNKa of the bank BNK. In this case, a part of the upper barrier UBR1a can be provided between the first emission layer EML1 and the second emission layer EML2 to overlap a part of the first emission layer EML1 and the second emission layer EML2. Accordingly, because a contact area of the upper barrier UBR1a and the P-type charge generation layer P-CGL is increased, the lateral leakage current can be blocked or further reduced by the sheet resistance of the upper barrier UBR1a.

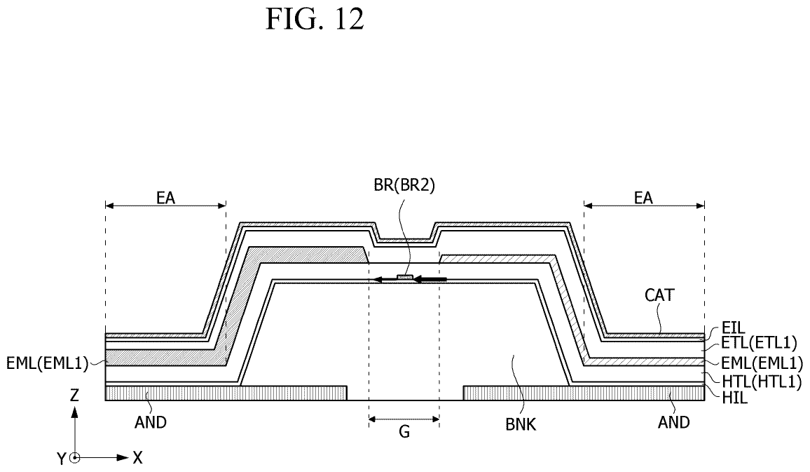

FIG. 12 is an enlarged view conceptually illustrating an example of an arrangement relationship between a second organic compound layer and a barrier with a B area of FIG. 6 as a reference. For example, FIG. 12 is an enlarged view conceptually illustrating a first embodiment of the present disclosure for an arrangement relationship between a second organic compound layer and a barrier. Arrows of FIG. 12 can represent a flow of a lateral leakage current. Here, a barrier BR illustrated in FIG. 12 can represent a second barrier according to the first embodiment.

Referring to FIG. 12, a second barrier BR2 can be provided inside the second organic compound layer EL2. In this case, the second barrier BR2 can be provided to overlap the bank BNK.

The second organic compound layer EL2 can include the hole injection layer HIL, the first hole transport layer HTL1, the first emission layer EML1, the first electron transport layer ETL1, the electron injection layer EIL provided on the first electron transport layer ETL1, and the second barrier BR2 provided on the hole injection layer HIL, but embodiments of the present disclosure are not necessarily limited thereto. For example, even when the first barrier BR1 is provided in the first organic compound layer EL1, the second barrier BR2 may not be positioned in the second organic compound layer EL2.

The second barrier BR2 can be provided on the hole injection layer HIL along with and in contact with the first hole transport layer HTL1. Here, the second barrier BR2 can be provided on the first path of the lateral leakage current like the lower barrier DBR1 of the first barrier BR1.

Because the second barrier BR2 can be provided in the same layer as the lower barrier DBR1 of the first barrier BR1 in terms of the position, the second barrier BR2 can be formed along with the first barrier BR1 in forming the first barrier BR1 using a mask.

As the material of the first hole transport layer HTL1 and the material of the second barrier BR2 are different, a sheet resistance of the first hole transport layer HTL1 and a sheet resistance of the second barrier BR2 can be different. For this reason, the lateral leakage current can be reduced while passing through the second barrier BR2. Referring to the arrows illustrated in FIG. 12, the lateral leakage current can be reduced primarily in a contact area of the second barrier BR2 and the hole injection layer HIL by the sheet resistance of the second barrier BR2. The lateral leakage current reduced primarily can be reduced secondarily in a contact area of the hole injection layer HIL and the first hole transport layer HTL1 by the sheet resistance of the first hole transport layer HTL1.

In the second organic compound layer EL2, the first emission layer EML1 that forms one emission area EA and the first emission layer EML1 that is provided neighboring thereto and forms another emission area EA can be provided spaced apart from each other to have a predetermined gap G. For example, the first emission layers EML1 provided adjacent to each other can be provided to have the predetermined gap G. In this case, the second barrier BR2 can be provided between two first emission layer EML1 provided adjacent to each other with the X-axis direction as a reference.

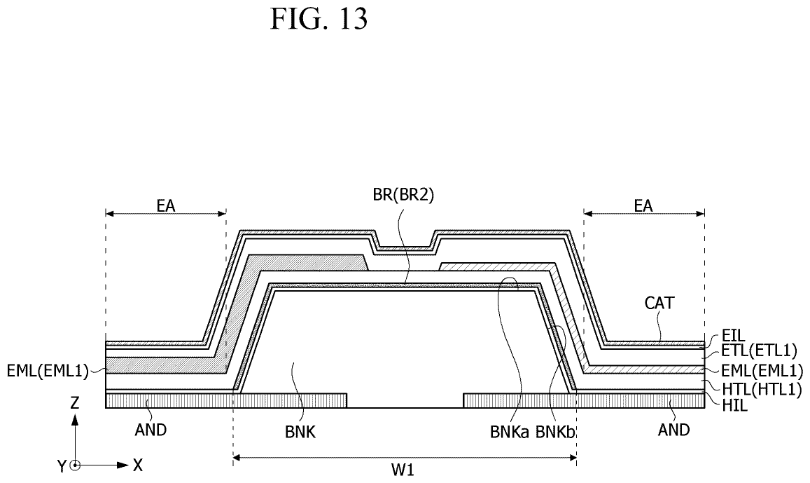

FIG. 13 is an enlarged view conceptually illustrating an example of an arrangement relationship between a second organic compound layer and a barrier with the B area of FIG. 6 as a reference. For example, FIG. 13 is an enlarged view conceptually illustrating a second embodiment of the present disclosure for an arrangement relationship between a second organic compound layer and a barrier. Here, a barrier BR illustrated in FIG. 13 can represent a second barrier according to the second embodiment.

Referring to FIGS. 12 and 13, a second barrier BR2a according to the second embodiment is different from the second barrier BR2 according to the first embodiment in that a width is increased. Accordingly, with the second barrier BR2a having the increased width, the lateral leakage current can be further reduced while passing through the second barrier BR2a.

The second barrier BR2a according to the second embodiment can be provided in the display panel 100 instead of the second barrier BR2 according to the first embodiment.

Referring to FIG. 13, the second barrier BR2a of the second organic compound layer EL2 can be provided on the hole injection layer HIL along with the first hole transport layer HTL1 and can overlap the bank BNK. In this case, the second barrier BR2a can be provided in contact with the hole injection layer HIL. Here, the second barrier BR2a can be provided on the first path of the lateral leakage current.

Because the second barrier BR2a can be provided in the same layer as the lower barrier DBR1a of the first barrier BR1a in terms of the position, the second barrier BR2a can be formed along with the lower barrier DBR1a in forming the lower barrier DBR1a using a mask.

A partial area of the second barrier BR2a can overlap the upper surface BNKa of the bank BNK. Further, another partial area of the second barrier BR2a can overlap a part or the whole of the side surface BNKb of the bank BNK. Accordingly, because a contact area of the second barrier BR2a and the hole injection layer HIL is increased, the lateral leakage current can be blocked or further reduced by the sheet resistance of the second barrier BR2a. In this case, a part of the second barrier BR2a can be provided to overlap a part of the first emission layer EML1; however, the width of the second barrier BR2a can be restricted in consideration of interference with the emission area EA. Here, a partial area of the second barrier BR2a overlapping the upper surface BNKa of the bank BNK can be a second barrier upper area, and another partial area of the second barrier BR2a overlapping the side surface BNKb of the bank BNK can be a second barrier lower area. In this case, because the bank BNK has a trapezoidal shape having predetermined height and width, the second barrier lower area can overlap the side surface BNKb of the bank BNK in the X-axis direction or the Y-axis direction. The second barrier lower area can overlap the side surface BNKb of the bank BNK in the Z-axis direction.

Accordingly, the display device according to the embodiments of the present disclosure can implement the barrier BR provided in the organic compound layer EL with a combination of one selected from the first barriers BR1 according to the first to fourth embodiments and one selected from the second barriers BR2 according to the first and second embodiments. In this case, the above-described combination can also include the organic compound layer EL implemented by only one selected from the first barriers BR1 according to the first to fourth embodiments without second barriers BR2 according to the first and second embodiments. For example, even when the barrier BR is not provided in the second organic compound layer EL2, the first organic compound layer EL1 can include one of the first barriers BR1 according to the first to fourth embodiments.

Two light-emitting elements OLED provided neighboring (adjacent) to each other can emit light of different colors. For example, one of the two light-emitting elements OLED provided neighboring to each other can be a blue light-emitting element, and the other can be a red light-emitting element, but embodiments of the present disclosure are not limited thereto. When the two light-emitting elements OLED provided neighboring to each other are light-emitting elements that implement the same color, the two light-emitting elements OLED can be relatively less affected by light due to the lateral leakage current than the two light-emitting elements OLED that are provided neighboring to each other and emit light of different colors. However, even when the two light-emitting elements OLED provided neighboring to each other implement the same color, when a delay time until the lateral leakage current reaches another light-emitting element OLED after the light-emitting element OLED emits light and delay of emission of the light-emitting element OLED caused by the delay time are taken into consideration, the barrier BR of the display panel 100 is effective from a viewpoint of preventing or minimizing the occurrence of light due to the lateral leakage current.

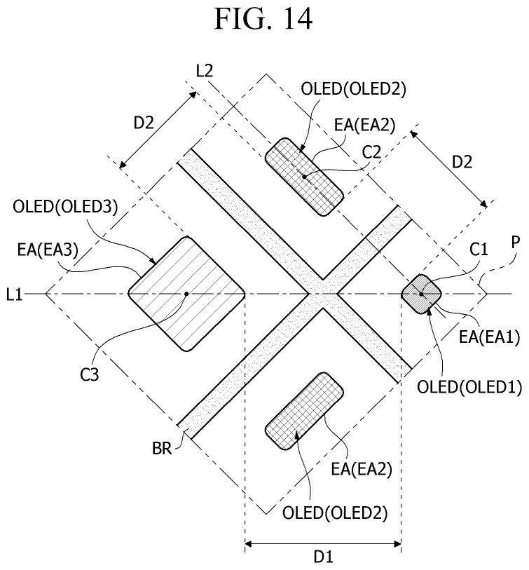

FIG. 14 is a diagram illustrating an example of a planar arrangement relationship between an emission area of a light-emitting element and a barrier in the display device according to the embodiments of the present disclosure. For example, FIG. 14 can be an enlarged view illustrating one pixel illustrated in FIG. 2 in terms of the plane. In FIG. 14, a frame represented by reference number OLED can represent an emission area EA of a light-emitting element OLED. A barrier BR illustrated in FIG. 14 can represent a planar arrangement of the first barrier BR1 provided in the first organic compound layer EL1 and the second barrier BR2 provided in the second organic compound layer EL2 in the arrangement relationship with the emission area EA.

The display panel 100 can include a plurality of light-emitting elements OLED corresponding to a plurality of subpixels. The light-emitting element OLED can include the emission area EA where light is emitted to the outside. For example, a first light-emitting element OLED1 can include a first emission area EA1, a second light-emitting element OLED2 can include a second emission area EA2, and a third light-emitting element OLED3 can include a third emission area EA3.

The first emission area EA1, the second emission area EA2, and the third emission area EA3 can generate light having different wavelengths. For example, because the first emission area EA1 can generate red light, the first light-emitting element OLED1 can be a red light-emitting element. Further, because the second emission area EA2 can generate green light, the second light-emitting element OLED2 can be a green light-emitting element. In addition, because the third emission area EA3 can generate blue light, the third light-emitting element OLED3 can be a blue light-emitting element.

Referring to FIG. 14, a plurality of emission areas EA can be provided spaced apart from each other. The barrier can be provided between two emission areas EA provided neighboring to each other.

The barrier BR can be provided along a circumference of the emission area EA. In this case, the barrier BR can be provided spaced apart from the emission area EA. Accordingly, the barrier BR can be provided on a virtual first line L1 that connects a center C1 of the first emission area EA1 and a center C3 of the third emission area EA3. Further, the barrier BR can be provided on a virtual second line L2 that connects the center C1 of the first emission area EA1 and a center C2 of the second emission area EA2. Here, the center C1 of the first emission area EA1 can be a first center, the center C2 of the second emission area EA2 can be a second center, and the center C3 of the third emission area EA3 can be a third center.

A plurality of emission areas EA can include the first emission area EA1, the second emission areas EA2 provided spaced apart from the first emission area EA1 at a predetermined distance D2, and the third emission area EA3 provided spaced apart from the first emission area EA1 at a predetermined distance D1. For example, the first emission area EA1 and the third emission area EA3 can be provided spaced apart from each other at a first distance D1. The second emission area EA2 and the third emission area EA3 can be provided spaced apart from each other at a second distance D2. In this case, the first distance D1 can be greater than the second distance D2. As the distance is farther, resistance becomes greater. For this reason, as the distance is farther, an amount of flowing current can be reduced. This principle can be applied to a lateral leakage current that flows between the first light-emitting element OLED1 and the third light-emitting element OLED3 and a lateral leakage current that flows between the second light-emitting element OLED2 and the third light-emitting element OLED3.

The display device according to the embodiments of the present disclosure can present various embodiments for a planar arrangement relationship between an emission area of a light-emitting element and a barrier in addition to the planar arrangement relationship between the emission area of the light-emitting element and the barrier illustrated in FIG. 14.

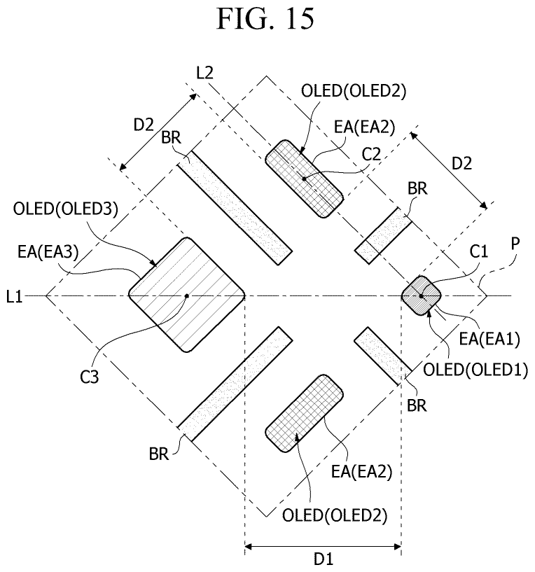

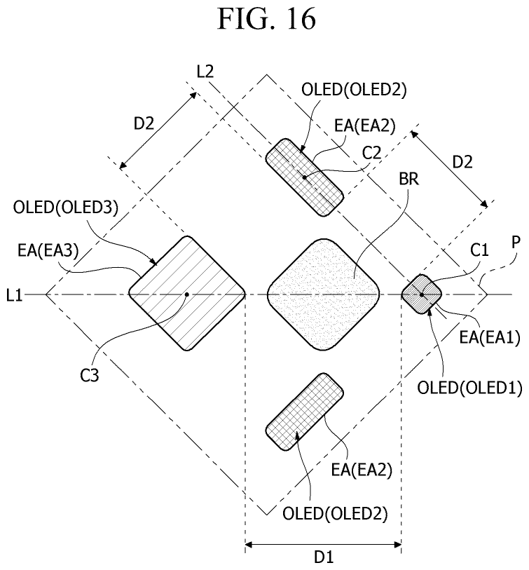

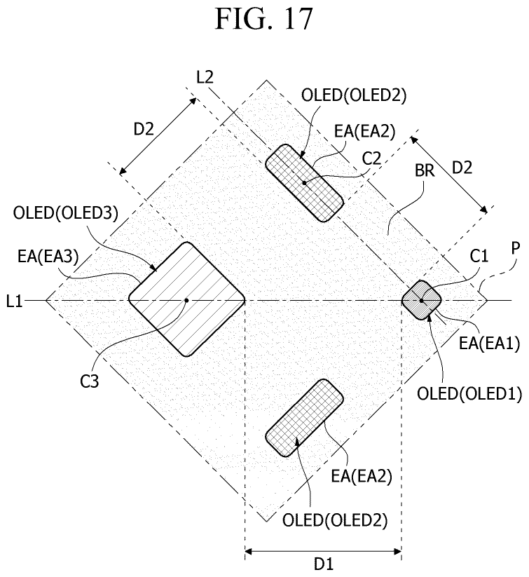

FIG. 15 is a diagram illustrating another example of a planar arrangement relationship between an emission area of a light-emitting element and a barrier in the display device according to the embodiments of the present disclosure. FIG. 16 is a diagram illustrating another example of a planar arrangement relationship between an emission area of a light-emitting element and a barrier in the display device according to the embodiments of the present disclosure. FIG. 17 is a diagram illustrating another example of a planar arrangement relationship between an emission area of a light-emitting element and a barrier in the display device according to the embodiments of the present disclosure.

Because light-emitting elements OLED illustrated in FIGS. 15 to 17 are substantially the same as the light-emitting elements OLED illustrated in FIG. 14 in terms of the arrangement structure, the light-emitting elements OLED are given the same reference numbers, and redundant description thereto will be omitted or simplified.

Referring to FIG. 15, in another example, a barrier BR can be provided on the virtual second line L2 that connects the center C1 of the first emission area EA1 and the center C2 of the second emission area EA2. In this case, the barrier BR may not be provided on the virtual first line L1 that connects the center C1 of the first emission area EA1 and the center C3 of the third emission area EA3.

Referring to FIG. 16, in another example, a barrier BR can be provided on the virtual first line L1 that connects the center C1 of the first emission area EA1 and the center C3 of the third emission area EA3. In this case, the barrier BR may not be provided on the virtual second line L2 that connects the center C1 of the first emission area EA1 and the center C2 of the second emission area EA2.

Referring to FIG. 17, in another example, the barrier BR can be provided on the virtual first line L1 that connects the center C1 of the first emission area EA1 and the center C3 of the third emission area EA3. Further, the barrier BR can be provided on the virtual second line L2 that connects the center C1 of the first emission area EA1 and the center C2 of the second emission area EA2. In this case, the barrier BR can be provided in the entire area excluding the emission area EA in terms of the plane.

A display device according to one or more embodiments of the present disclosure will be described below.

A display device according to one or more embodiments of the present disclosure can include a display panel including a first display area having a transmission area and a second display area, and a sensor provided corresponding to the first display area. The display panel can include a substrate, a circuit layer provided on the substrate, an anode electrode provided on the circuit layer, an organic compound layer that is provided on the anode electrode and includes a plurality of emission areas, a cathode electrode provided on the organic compound layer, and a plurality of barriers positioned in the organic compound layer.

According to one or more embodiments of the present disclosure, the organic compound layer of the first display area can include two emission layers, and the organic compound layer of the second display area can include one emission layer.

According to one or more embodiments of the present disclosure, the display panel can further include a bank provided on a planarization layer of the circuit layer, and the barriers can be provided to overlap the bank.

According to one or more embodiments of the present disclosure, the organic compound layer can include a first organic compound layer of the first display area and a second organic compound layer of the second display area. The first organic compound layer can include a hole injection layer, a first hole transport layer provided on the hole injection layer, a first emission layer provided on the first hole transport layer, a first electron transport layer provided on the first emission layer, a charge generation layer provided on the first electron transport layer, a second hole transport layer provided on the charge generation layer, a second emission layer provided on the second hole transport layer, a second electron transport layer provided on the second emission layer, and an electron injection layer provided on the second electron transport layer. The plurality of barriers can include at least one of a lower barrier provided on the hole injection layer and an upper barrier provided on the charge generation layer.

According to one or more embodiments of the present disclosure, the charge generation layer can include a first charge generation layer provided on the first electron transport layer and a second charge generation layer provided on the first charge generation layer, and the upper barrier can be provided on the second charge generation layer.

According to one or more embodiments of the present disclosure, a material of the lower barrier can be different from a material of the first hole transport layer, and a material of the upper barrier can be different from a material of the second hole transport layer.

According to one or more embodiments of the present disclosure, each of the lower barrier and the upper barrier can include the same material as a material of the electron injection layer.

According to one or more embodiments of the present disclosure, the display panel can further include a bank provided on a planarization layer of the circuit layer, and the barrier provided in the first organic compound layer can be provided to overlap the bank.

According to one or more embodiments of the present disclosure, the display panel can further include a bank provided on a planarization layer of the circuit layer, and the barriers provided in the first organic compound layer can be provided spaced apart from the bank.

According to one or more embodiments of the present disclosure, the bank can include an upper surface and a side surface, and the lower barrier can be provided to overlap the side surface of the bank.

According to one or more embodiments of the present disclosure, the upper barrier can be provided to overlap the upper surface of the bank.

According to one or more embodiments of the present disclosure, the lower barrier can be provided not to overlap the second emission layer, and the upper barrier can be provided to overlap the second emission layer.

According to one or more embodiments of the present disclosure, the lower barrier and the upper barrier can be provided to overlap each other.

According to one or more embodiments of the present disclosure, a part of the first hole transport layer can be provided on the lower barrier, and a part of the second hole transport layer can be provided on the upper barrier.

According to one or more embodiments of the present disclosure, the second organic compound layer can include a hole injection layer, a first hole transport layer provided on the hole injection layer, a first emission layer provided on the first hole transport layer, a first electron transport layer provided on the first emission layer, and an electron injection layer provided on the first electron transport layer, and the plurality of barriers can include a barrier provided on the hole injection layer.

According to one or more embodiments of the present disclosure, the display panel can further include a bank provided on a planarization layer of the circuit layer, and the barriers provided in the second organic compound layer can be provided to overlap the bank.

According to one or more embodiments of the present disclosure, the plurality of emission areas can include a first emission area and a second emission area provided spaced apart from the first emission area at a predetermined distance, the first emission area and the second emission area can generate light having different wavelengths, and the barriers can be provided on a virtual first line that connects a center of the first emission area and a center of the second emission area.

According to one or more embodiments of the present disclosure, the plurality of emission areas can further include a third emission area provided spaced apart from the first emission area at a predetermined distance, the first emission area, the second emission area, and the third emission area can generate light having different wavelengths, and the barriers can be further provided on a virtual second line that connects the center of the first emission area and a center of the third emission area. The first emission area and the third emission area can be provided spaced apart from each other at a first distance. The second emission area and the third emission area can be provided spaced apart from each other at a second distance. The first distance can be greater than the second distance.

According to one or more embodiments of the present disclosure, the plurality of emission areas can include a third emission area provided spaced apart from the first emission area at a predetermined distance, the first emission area, the second emission area, and the third emission area can generate light having different wavelengths, and the barriers can be provided on a virtual line that connects a center of the first emission area and a center of the third emission area.

According to one or more embodiments of the present disclosure, a first distance between the first emission area and the third emission area can be greater than a second distance between the second emission area and the third emission area.

According to one or more embodiments of the present disclosure, the barrier can be provided between two emission areas provided neighboring to each other.

According to one or more embodiments of the present disclosure, the barrier can be provided along a circumference of the emission area.

A display device according to one or more embodiments of the present disclosure can include a substrate, a circuit layer provided on the substrate, an anode electrode provided on the circuit layer, an organic compound layer provided on the anode electrode, and a cathode electrode provided on the organic compound layer. The organic compound layer can include a hole injection layer, a barrier and a hole transport layer provided on the hole injection layer to be in contact with each other, an emission layer provided on the hole transport layer, an electron transport layer provided on the emission layer, and an electron injection layer provided on the electron transport layer. A material of the barrier and a material of the hole transport layer can be different.

According to one or more embodiments of the present disclosure, a sheet resistance on an interface at which the barrier and the hole injection layer are in contact with each other can be greater than a sheet resistance on an interface at which the barrier and the hole transport layer are in contact with each other.

According to one or more embodiments of the present disclosure, the barrier can include the same material as a material of the electron injection layer.

According to one or more embodiments of the present disclosure, the display device can further include a bank provided on a planarization layer of the circuit layer, in which the barrier can be provided to overlap the bank.

According to one or more embodiments of the present disclosure, the substrate can include a first display area having a transmission area and a second display area, the organic compound layer of the first display area can include two emission layers, and the organic compound layer of the second display area can include one emission layer.

According to one or more embodiments of the present disclosure, the organic compound layer can include a plurality of emission areas, and the barrier can be provided between two emission areas provided neighboring to each other.

According to one or more embodiments of the present disclosure, the plurality of emission areas can include a first emission area, a second emission area provided spaced apart from the first emission area at a predetermined distance, and a third emission area provided spaced apart from the first emission area at a predetermined distance, the first emission area, the second emission area, and the third emission area can generate light having different wavelengths, and the barriers can be provided on a virtual line that connects a center of the first emission area and a center of the third emission area.

The objects to be achieved by the present disclosure, the means for achieving the objects, and effects of the present disclosure described above do not specify essential features of the claims, and thus, the scope of the claims is not limited to the disclosure of the present disclosure.

Although the embodiments of the present disclosure have been described in more detail with reference to the accompanying drawings, the present disclosure is not limited thereto and can be embodied in many different forms without departing from the technical concept of the present disclosure. Therefore, the embodiments disclosed in the present disclosure are provided for illustrative purposes only and are not intended to limit the technical concept of the present disclosure. The scope of the technical concept of the present disclosure is not limited thereto. Therefore, it should be understood that the above-described embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device comprising:
a display panel including a first display area and a second display area; and
a sensor corresponding to the first display area,
wherein the display panel includes:
a substrate;
a circuit layer provided on the substrate;
an anode electrode provided on the circuit layer;
an organic compound layer provided on the anode electrode and including a plurality of emission areas;
a cathode electrode provided on the organic compound layer; and
a plurality of barriers positioned in the organic compound layer.

2. The display device according to claim 1, wherein:
the organic compound layer of the first display area includes two emission layers, and
the organic compound layer of the second display area includes one emission layer.

3. The display device according to claim 1, wherein:
the display panel further includes a bank provided on a planarization layer of the circuit layer, and
the plurality of barriers are provided to overlap the bank.

4. The display device according to claim 1, wherein the organic compound layer includes a first organic compound layer of the first display area and a second organic compound layer of the second display area,
wherein the first organic compound layer includes:
a hole injection layer;
a first hole transport layer provided on the hole injection layer;
a first emission layer provided on the first hole transport layer;
a first electron transport layer provided on the first emission layer;
a charge generation layer provided on the first electron transport layer;
a second hole transport layer provided on the charge generation layer;
a second emission layer provided on the second hole transport layer;
a second electron transport layer provided on the second emission layer; and
an electron injection layer provided on the second electron transport layer, and
wherein the plurality of barriers include at least one of a lower barrier provided on the hole injection layer and an upper barrier provided on the charge generation layer.

5. The display device according to claim 4, wherein:
the charge generation layer includes a first charge generation layer provided on the first electron transport layer and a second charge generation layer provided on the first charge generation layer, and
the upper barrier is provided on the second charge generation layer.

6. The display device according to claim 4, wherein:
a material of the lower barrier is different from a material of the first hole transport layer,
a material of the upper barrier is different from a material of the second hole transport layer, and
each of the lower barrier and the upper barrier includes the same material as a material of the electron injection layer.

7. The display device according to claim 4, wherein:
the display panel further includes a bank provided on a planarization layer of the circuit layer, and
the plurality of barriers provided in the first organic compound layer are provided to overlap the bank.

8. The display device according to claim 7, wherein:
the bank includes an upper surface and a side surface,
the lower barrier is provided to overlap the side surface of the bank, and
the upper barrier is provided to overlap the upper surface of the bank.

9. The display device according to claim 4, wherein:
the lower barrier is provided not to overlap the second emission layer, and
the upper barrier is provided to overlap the second emission layer.

10. The display device according to claim 4, wherein the lower barrier and the upper barrier are provided to overlap each other.

11. The display device according to claim 4, wherein the second organic compound layer includes:
a hole injection layer;
a first hole transport layer provided on the hole injection layer;
a first emission layer provided on the first hole transport layer;
a first electron transport layer provided on the first emission layer; and
an electron injection layer provided on the first electron transport layer, and
wherein the plurality of barriers include a barrier provided on the hole injection layer.

12. The display device according to claim 11, wherein:
the display panel further includes a bank provided on a planarization layer of the circuit layer, and
the plurality of barriers provided in the second organic compound layer are provided to overlap the bank.

13. The display device according to claim 1, wherein:
the plurality of emission areas include a first emission area and a second emission area provided spaced apart from the first emission area at a predetermined distance,
the first emission area and the second emission area are configured to generate light having different wavelengths, and
the plurality of barriers are provided on a virtual first line that connects a center of the first emission area and a center of the second emission area.

14. The display device according to claim 13, wherein:
the plurality of emission areas further include a third emission area provided spaced apart from the first emission area at a predetermined distance,
the first emission area, the second emission area, and the third emission area are configured to generate light having different wavelengths, and
the plurality of barriers are further provided on a virtual second line that connects the center of the first emission area and a center of the third emission area.

15. The display device according to claim 1, wherein:
the plurality of emission areas include a first emission area, a second emission area provided spaced apart from the first emission area at a predetermined distance, and a third emission area provided spaced apart from the first emission area at a predetermined distance,
the first emission area, the second emission area, and the third emission area are configured to generate light having different wavelengths, and
the plurality of barriers are provided on a virtual line that connects a center of the first emission area and a center of the third emission area.

16. A display device comprising:
a substrate;
a circuit layer provided on the substrate;
an anode electrode provided on the circuit layer;
an organic compound layer provided on the anode electrode; and
a cathode electrode provided on the organic compound layer,
wherein the organic compound layer includes:
a hole injection layer;
a barrier and a hole transport layer provided on the hole injection layer in contact with each other;
an emission layer provided on the hole transport layer;
an electron transport layer provided on the emission layer; and
an electron injection layer provided on the electron transport layer, and
wherein a material of the barrier and a material of the hole transport layer are different.

17. The display device according to claim 16, wherein a sheet resistance on an interface at which the barrier and the hole injection layer are in contact with each other is greater than a sheet resistance on an interface at which the barrier and the hole transport layer are in contact with each other.

18. The display device according to claim 17, wherein the barrier includes the same material as a material of the electron injection layer.

19. The display device according to claim 16, wherein:
the substrate includes a first display area having a transmission area and a second display area,
the organic compound layer of the first display area includes two emission layers, and
the organic compound layer of the second display area includes one emission layer.

20. The display device according to claim 16, wherein:
the organic compound layer includes a plurality of emission areas, and
the barrier is provided between two neighboring emission areas among the plurality of emission areas.
